(19) United States
(12) Patent Application Publication
(10) Pub. No.: US 2026/0136646 A1
(43) Pub. Date: May 14, 2026

(54) SEMICONDUCTOR DEVICE

(71) Applicant: Samsung Electronics Co., Ltd., Suwon-si (KR)

(72) Inventors: Pilkwang KIM, Suwon-si (KR); Seunghyun SONG, Suwon-si (KR); Sungil PARK, Suwon-si (KR); Yonghee PARK, Suwon-si (KR); Kyeongrim KIM, Suwon-si (KR); Changju MOON, Suwon-si (KR); Young-Seok SONG, Suwon-si (KR)

(73) Assignee: Samsung Electronics Co., Ltd., Suwon-si (KR)

(21) Appl. No.: 19/189,622

(22) Filed: Apr. 25, 2025

(30) Foreign Application Priority Data
Nov. 8, 2024 (KR) 10-2024-0158513

(51) Int. Cl. H10D 84/40; H10D 84/01

(52) U.S. Cl. CPC H10D 84/40; H10D 84/0109

(57) ABSTRACT

Provided is a semiconductor device including a lower sheet structure including a plurality of first lower semiconductor layers and a plurality of second lower semiconductor layers alternately stacked, an upper sheet structure including a plurality of first upper semiconductor layers and a plurality of second upper semiconductor layers alternately stacked on the lower sheet structure, a lower semiconductor pattern on at least one side of the lower sheet structure, an upper semiconductor pattern on at least one side of the upper sheet structure, and a PN junction structure between the lower sheet structure and the upper sheet structure, the PN junction structure including a P-type and an N-type semiconductor material. The PN junction structure includes a first doped layer having first-type conductivity on the lower sheet structure, and a second doped layer having second-type conductivity on the first doped layer.

### CROSS-REFERENCE TO RELATED APPLICATION

This application claims priority to and the benefit of Korean Patent Application No. 10-2024-0158513 filed in the Korean Intellectual Property Office on Nov. 8, 2024, the entire contents of which are incorporated herein by reference.

### BACKGROUND

Example embodiments of the present disclosure relate to a semiconductor device.

A semiconductor is a material that belongs to an intermediate region between a conductor and an insulator, and indicates a material that conducts electricity under desired (and/or alternatively predetermined) conditions. Such semiconductor materials may be used to manufacture various semiconductor devices, for example, memory devices. The semiconductor devices may be used in various electronic devices.

As the electronics industry continues to develop, a demand for an advanced features of semiconductor devices is continually increasing. For example, there is an increasing demand for semiconductor devices implementing higher reliability, higher speed, and/or multi-functionality. Accordingly, structures within semiconductor devices continue to become increasingly complex and integrated.

### SUMMARY

Some example embodiments of the present disclosure provide a transistor structure and a stacked structure disposed on a base insulating layer and/or a semiconductor substrate. Accordingly, a stacked structure including a diode element or the like may be formed together with a transistor structure without significantly increasing the number of manufacturing processes.

According to some example embodiments, a semiconductor device includes a lower sheet structure including a plurality of first lower semiconductor layers and a plurality of second lower semiconductor layers alternately stacked, an upper sheet structure including a plurality of first upper semiconductor layers and a plurality of second upper semiconductor layers alternately stacked on the lower sheet structure, a lower semiconductor pattern on at least one side of the lower sheet structure, an upper semiconductor pattern on at least one side of the upper sheet structure, and a PN junction structure between the lower sheet structure and the upper sheet structure, the PN junction structure including a P-type and an N-type semiconductor material. The PN junction structure includes a first doped layer having first-type conductivity on the lower sheet structure, and a second doped layer having second-type conductivity on the first doped layer.

According to some example embodiments, a semiconductor device includes a lower sheet structure having first-type conductivity and including a plurality of first lower semiconductor layers and a plurality of second lower semiconductor layers alternately stacked, an upper sheet structure having second-type conductivity and including a plurality of first upper semiconductor layers and a plurality of second upper semiconductor layers alternately stacked on the lower sheet structure, a lower semiconductor pattern on at least one side of the lower sheet structure, and a PN junction structure between the plurality of first lower semiconductor layers and the plurality of first upper semiconductor layers, the PN junction structure including a P-type and an N-type semiconductor material, and a same material as at least one of the plurality of second lower semiconductor layers and the plurality of second upper semiconductor layers. The PN junction structure includes a first doped layer having the first-type conductivity on the lower sheet structure, and a second doped layer having the second-type conductivity between the first doped layer and the upper sheet structure.

According to some example embodiments, a semiconductor device includes a base insulating layer, a lower sheet structure including a plurality of first lower semiconductor layers and a plurality of second lower semiconductor layers alternately stacked on the base insulating layer, an upper sheet structure including a plurality of first upper semiconductor layers and a plurality of second upper semiconductor layers alternately stacked on the lower sheet structure, a lower semiconductor pattern having first-type conductivity on at least one side of the lower sheet structure, an upper semiconductor pattern having second-type conductivity on at least one side of the upper sheet structure, a barrier structure between the lower semiconductor pattern and the upper semiconductor pattern, and a PN junction structure between the lower sheet structure and the upper sheet structure and overlapping the barrier structure, the PN junction structure including a P-type and an N-type semiconductor material. The PN junction structure includes a first doped layer having the first-type conductivity on the lower sheet structure, and a second doped layer having the second-type conductivity on the first doped layer, and a doping concentration of first-type conductivity impurities in the first doped layer is less than or equal to a doping concentration of the first-type conductivity impurities in the lower semiconductor pattern.

According to some example embodiments, a method of manufacturing a semiconductor device includes forming an active pattern on a substrate, forming a first stack on the active pattern in a first region of the substrate including a preliminary lower sheet structure, a first preliminary intermediate insulating structure, a preliminary upper sheet structure, and a first sacrificial gate structure, forming a second stack on the active pattern in a second region of the substrate including a lower sacrificial layer, an upper sacrificial layer, a plurality of lower channel patterns, a second preliminary intermediate insulating structure, a plurality of upper channel patterns, and a second sacrificial gate structure, forming a first sacrificial gate structure on the first stack and a second sacrificial gate structure on the second stack, etching the first stack using the first sacrificial gate structure as an etching mask to form a first recess, and etching the second stack using the first sacrificial gate structure as an etching mask to form a second recess, and forming a lower semiconductor pattern and a first barrier structure in the first recess, forming a lower source/drain pattern, and a second barrier structure in the second recess, forming an upper semiconductor pattern on the first barrier structure, and an upper source/drain pattern on the second barrier structure, forming a first lower sheet structure, a first upper sheet structure, a first doped layer and a second doped layer using a heat treatment process, forming an interlayer insulating layer on the upper semiconductor pattern and the upper source/drain pattern, forming an upper gate trench in the first region and the second region by removing at least a portion of the first sacrificial gate structure and the second sacrificial gate structure, removing the second preliminary intermediate insulating structure in the second region and forming a gap and forming an intermediate insulating structure in the gap, removing the upper sacrificial layer and lower sacrificial layer to form a lower gate trench, forming an upper gate structure and a lower gate structure in the lower gate trench, forming a dummy main gate structure in the upper gate trench in the first region and a main gate structure in the upper gate trench in the second region, forming an upper contact structure penetrating the interlayer insulating layer to contact the upper semiconductor pattern in the first region and the upper source/drain pattern in the second region, removing the substrate and the active pattern and forming a base insulating layer and a protruding pattern in place of the substrate and the active pattern, respectively, and forming a lower contact structure penetrating the base insulating layer and the protruding pattern.

According to some example embodiments, the method of manufacturing the semiconductor device further includes in the forming of the first lower sheet structure, the first upper sheet structure, the first doped layer and a second doped layer the heat treatment process diffuses impurities from the lower semiconductor pattern and the upper semiconductor pattern into the preliminary lower sheet structure, and the preliminary upper sheet structure to form the first lower sheet structure, and the first upper sheet structure, and the heat treatment process further forms a first doped layer by diffusing impurities into a first portion of the first preliminary intermediate insulating structure using the heat treatment process, and a second doped layer by diffusing impurities into a second portion of the first preliminary intermediate insulating structure.

As described above, the semiconductor device according to some example embodiments may include a stacked structure formed to include a diode element or the like together with a transistor structure without significantly increasing the number of manufacturing processes.

### BRIEF DESCRIPTION OF THE DRAWINGS

FIG. 1 is a plan view showing a semiconductor device according to some example embodiments.

FIG. 2 is a cross-sectional view taken along lines A-A′ and B-B′ of FIG. 1.

FIG. 3 is a cross-sectional view taken along line C-C′ of FIG. 1.

FIG. 4 is a cross-sectional view taken along line D-D′ of FIG. 1.

FIG. 5 is a cross-sectional view showing an enlarged view of region S1 shown in FIG. 2.

FIGS. 6 to 10 are cross-sectional views corresponding to region S1 in FIG. 2 and showing a semiconductor device according to some example embodiments.

FIGS. 11 to 13 are cross-sectional views corresponding to a region taken along line A-A′ in FIG. 1 and showing a semiconductor device according to some example embodiments.

FIGS. 14 to 21 are cross-sectional views showing intermediate stages of a method for manufacturing a semiconductor device according to some example embodiments.

FIGS. 22 to 24 are cross-sectional views showing intermediate stages of a method for manufacturing a semiconductor device according to some example embodiments.

### DETAILED DESCRIPTION

Hereinafter, various example embodiments of the present disclosure are described in detail with reference to the accompanying drawings so that those skilled in the art to which the present disclosure pertains may easily practice the present disclosure. The present disclosure may be modified in various different forms, and is not limited to the example embodiments provided in the specification.

A portion unrelated to the description is omitted in order to clearly describe the present disclosure, and the same or similar components are denoted by the same reference numeral throughout the specification.

In addition, the size and thickness of each component shown in the accompanying drawings are arbitrarily shown for convenience of description, and therefore, the present disclosure is not necessarily limited to contents shown in the drawings. The thicknesses are exaggerated in the drawings in order to clearly represent several layers and regions. In addition, the thicknesses of some layers and regions are exaggerated in the drawings for convenience of description.

In addition, when an element such as a layer, a film, a region, or a plate is referred to as being “on” or “above” another element, the element may be “directly on” another element or may have a third element interposed therebetween. On the other hand, when an element is referred to as being “directly on” another element, there is no third element interposed therebetween. In addition, when an element is referred to as being “on” or “above” a reference element, the element may be disposed on or below the reference element, and may not necessarily be “on” or “above” the reference element in an opposite direction of gravity.

In addition, when any one part “includes” any one component, it may indicate the inclusion of other components rather than the exclusion of other components unless explicitly described to the contrary.

In addition, throughout the specification, an expression “on the plane” may indicate a case where a target is viewed from the top, and an expression “on the cross section” may indicate a case where a cross section of the target taken in a vertical direction is viewed from its side.

In the drawings of a semiconductor device according to some example embodiments, for example, the semiconductor device may include a gate all around (GAA), three-dimensional (3D) stack field effect transistor (3DSFET) structure, or the like, in which four sides of its channel are surrounded by gate electrodes. However, example embodiments are not limited thereto, and the transistor may include a fin field effect transistor (FinFET) structure, a multi bridge channel field effect transistor (MBCFET™) structure, a complementary field effect transistor (CFET) structure, or the like.

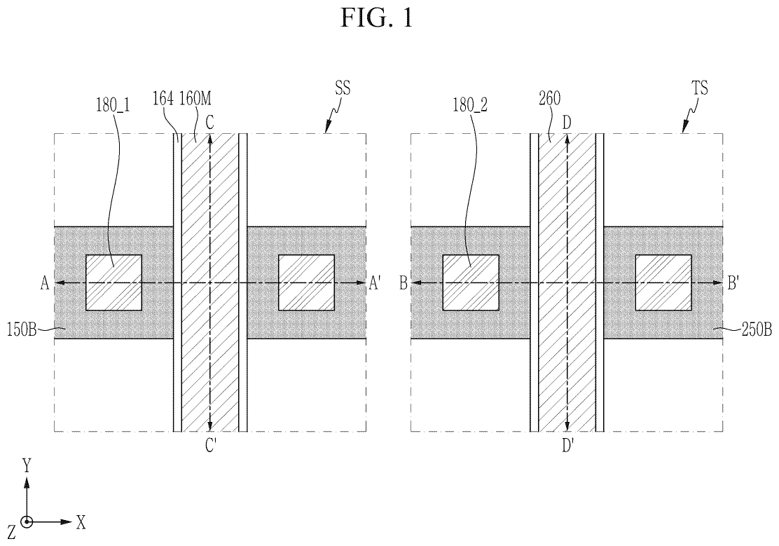

Hereinafter, a semiconductor device according to some example embodiments is described with reference to FIGS. 1 to 5.

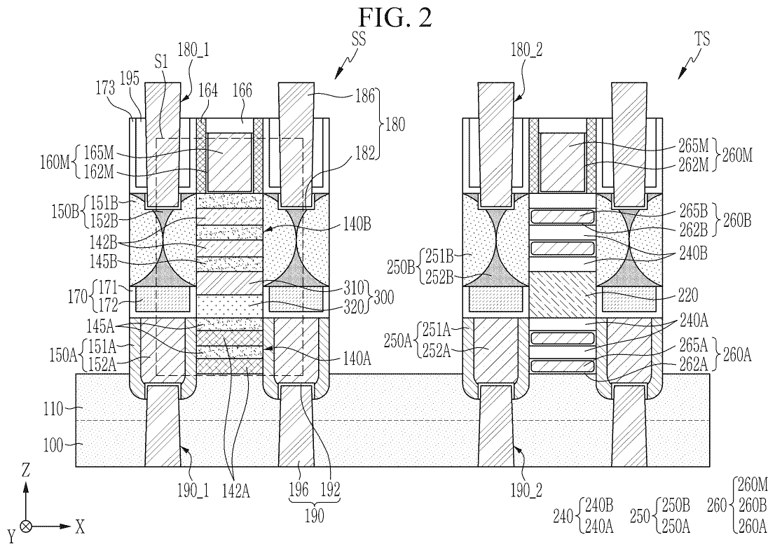

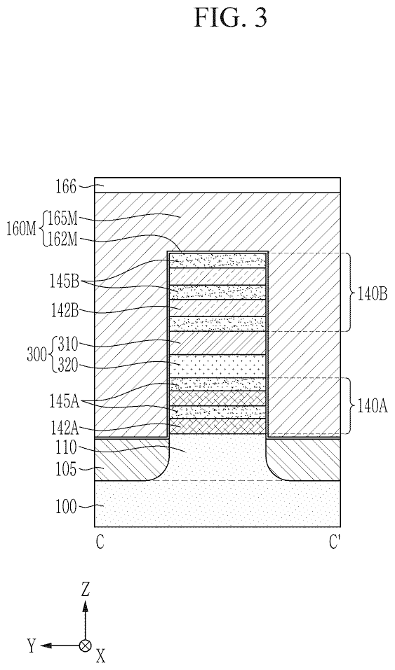

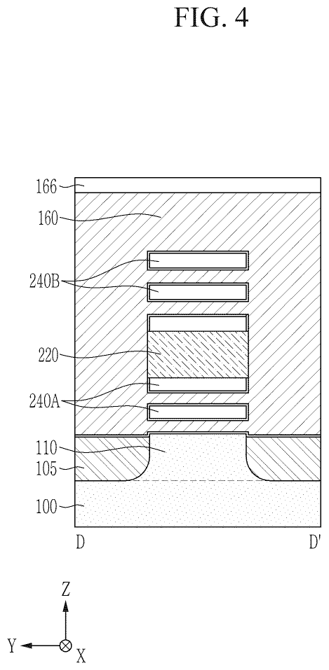

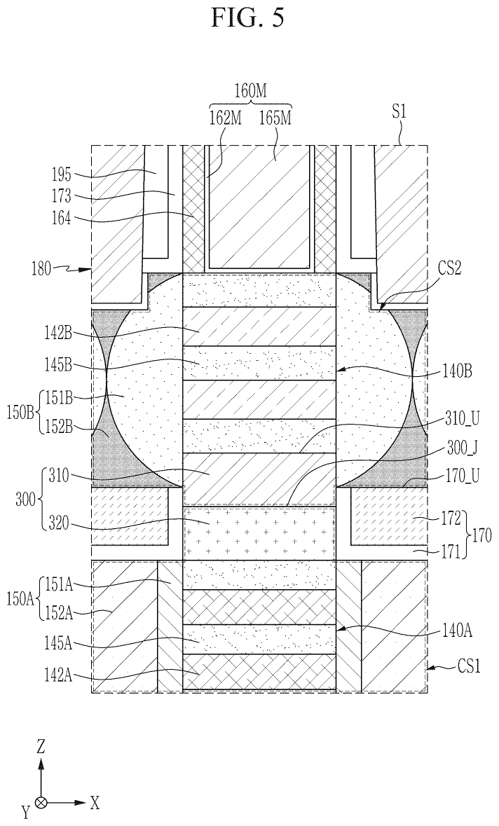

FIG. 1 is a plan view showing a semiconductor device according to some example embodiments. FIG. 2 is a cross-sectional view taken along lines A-A′ and B-B′ of FIG. 1. FIG. 3 is a cross-sectional view taken along line C-C′ of FIG. 1. FIG. 4 is a cross-sectional view taken along line D-D′ of FIG. 1. FIG. 5 is a cross-sectional view showing an enlarged view of region S1 shown in FIG. 2.

Referring to FIGS. 1 to 5, the semiconductor device according to some example embodiments may include a base insulating layer 100, a stacked structure SS and a transistor structure TS, disposed on the base insulating layer 100.

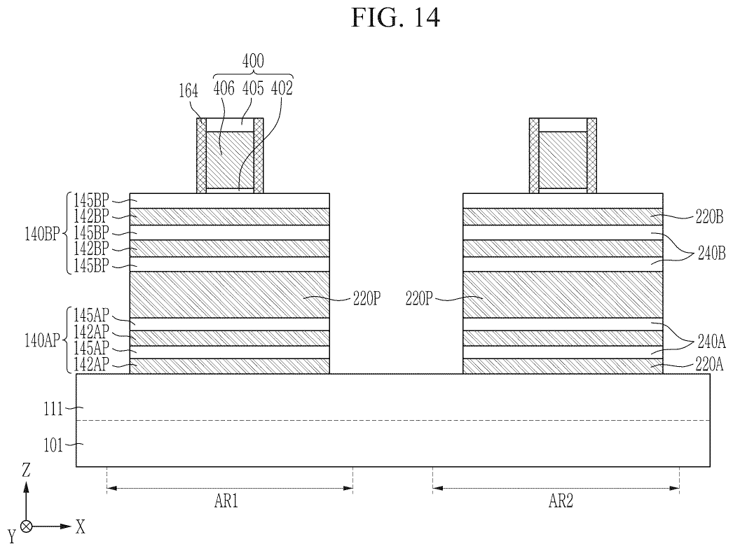

The base insulating layer 100 may be an insulation substrate. The base insulating layer 100 may include oxide, nitride, oxynitride, or combinations thereof. However, example embodiments are not limited thereto. For example, the base insulating layer 100 may include silicon oxide (SiO₂). The base insulating layer 100 is shown as a single film, which is only for convenience of description, and example embodiments are not limited thereto. The base insulating layer 100 may be formed by removing a substrate 101 (in FIG. 14) to be described below, and filling the removed portion of the substrate 101 (in FIG. 14) with an insulating material.

The base insulating layer 100 may include an upper surface and a lower surface. The upper surface and the lower surface of the base insulating layer 100 may be formed as planes parallel to a first direction (X direction) and a second direction (Y direction) intersecting the first direction (X direction). The upper surface of the base insulating layer 100 may be a surface opposite to the lower surface of the base insulating layer 100 in a third direction (Z direction). The upper surface of the base insulating layer 100 may be referred to as a front side. The lower surface of the base insulating layer 100 may be referred to as a back side.

The stacked structure SS and the transistor structure TS may be provided on the base insulating layer 100. The stacked structure SS and the transistor structure TS may be disposed on the base insulating layer 100. In some example embodiments, the stacked structure SS and the transistor structure TS are shown to be spaced apart from each other in the first direction (X direction), but example embodiments are not limited thereto. For example, the stacked structure SS and the transistor structure TS may be spaced apart from each other in the second direction (Y direction). Here, the second direction (Y direction) may be a direction intersecting the first direction (X direction). In some example embodiments, the second direction (Y direction) may be a direction intersecting the first direction (X direction).

Hereinafter, the description describes the stacked structure SS.

The stacked structure SS of the semiconductor device according to some example embodiments may include a lower sheet structure 140A disposed above the base insulating layer 100, an upper sheet structure 140B disposed above the lower sheet structure 140A, a lower semiconductor pattern 150A disposed on at least one side of the lower sheet structure 140A, an upper semiconductor pattern 150B disposed on at least one side of the upper sheet structure 140B, and a PN junction structure 300 including a P-type and an N-type semiconductor material disposed between the lower sheet structure 140A and the upper sheet structure 140B.

The stacked structure SS of the semiconductor device according to some example embodiments may further include a protruding pattern 110 disposed on the base insulating layer 100.

The protruding pattern 110 may be disposed on the base insulating layer 100. The protruding pattern 110 may extend in the first direction (X direction). The protruding pattern 110 may protrude from the base insulating layer 100 in the third direction (Z direction). The protruding pattern 110 may include the variety of insulating materials. The protruding pattern 110 may include the same material as the base insulating layer 100.

The lower sheet structure 140A may be disposed above the base insulating layer 100. The lower sheet structure 140A may be disposed on an upper surface of the protruding pattern 110. The lower sheet structure 140A may have first-type conductivity. The first-type conductivity may be P-type conductivity. For example, the lower sheet structure 140A may include boron (B), vanadium (V), indium (In), gallium (Ga), aluminum (Al), or a combination thereof. However, example embodiments are not limited thereto.

The lower sheet structure 140A according to some example embodiments may include a plurality of first lower semiconductor layers 145A and a plurality of second lower semiconductor layers 142A that are alternately stacked. In some example embodiments, the plurality of first lower semiconductor layers 145A may have a structure, shape, and arrangement relationship similar to those of a plurality of lower channel patterns 240A of the transistor structure TS to be described below, and the plurality of second lower semiconductor layers 142A may have a structure, shape, and arrangement relationship similar to those of a lower sacrificial layer 220A (in FIG. 14) of the transistor structure TS to be described below.

The plurality of first lower semiconductor layers 145A may be disposed above the protruding pattern 110. The plurality of first lower semiconductor layers 145A may be spaced apart from the protruding pattern 110 in the third direction (Z direction). The plurality of first lower semiconductor layers 145A may be spaced apart from each other in the third direction (Z direction). Here, the third direction (Z direction) may be a direction intersecting the first direction (X direction) and the second direction (Y direction). For example, the third direction (Z direction) may be a thickness direction of the base insulating layer 100. In some example embodiments, the plurality of first lower semiconductor layers 145A may have substantially the same width in the first direction (X direction), but example embodiments are not limited thereto. As another example, the plurality of first lower semiconductor layers 145A may have a width in the first direction (X direction) that is smaller as the plurality of first lower semiconductor layers 145A gets farther from the upper surface of the base insulating layer 100.

The plurality of first lower semiconductor layers 145A may include the semiconductor material. For example, the plurality of first lower semiconductor layers 145A may include an elemental semiconductor material, such as silicon (Si) or germanium (Ge). The plurality of first lower semiconductor layers 145A may be formed by etching a portion of the substrate 101 (in FIG. 14), or may include an epitaxial layer grown from the substrate 101 (in FIG. 14).

The plurality of first lower semiconductor layers 145A may include a compound semiconductor, for example, a group IV-IV compound semiconductor or a group III-V compound semiconductor. Here, the group IV-IV compound semiconductor may be, for example, a binary compound or a ternary compound including at least two or more of carbon (C), silicon (Si), germanium (Ge), and tin (Sn). The group III-V compound semiconductor may be, for example, a binary compound, a ternary compound, or a quaternary compound formed by coupling at least one of aluminum (Al), gallium (Ga), and indium (In) as group III elements with one of phosphorus (P), arsenic (As), and antimony (Sb) as group V elements. However, example embodiments are not limited thereto.

In some example embodiments, the plurality of first lower semiconductor layers 145A may include silicon (Si). As another example, the plurality of first lower semiconductor layers 145A may include silicon germanium (SiGe).

The plurality of first lower semiconductor layers 145A may have the first-type conductivity. The plurality of first lower semiconductor layers 145A may be doped with first-type conductivity impurities. Here, the first-type conductivity may be the P-type conductivity, but example embodiments are not limited thereto. For example, the plurality of first lower semiconductor layers 145A may include boron (B), vanadium (V), indium (In), gallium (Ga), aluminum (Al), or the combination thereof. However, example embodiments are not limited thereto.

The plurality of second lower semiconductor layers 142A may be disposed on the protruding pattern 110. The plurality of second lower semiconductor layers 142A may be stacked while being spaced apart from each other in the third direction (Z direction). The plurality of first lower semiconductor layers 145A may be disposed between the plurality of second lower semiconductor layers 142A stacked while being spaced apart from each other in the third direction (Z direction). That is, the plurality of first lower semiconductor layers 145A and the plurality of second lower semiconductor layers 142A may be alternately stacked in the third direction (Z direction). The lowermost second lower semiconductor layer 142A may be in contact with the protruding pattern 110, but example embodiments are not limited thereto. In some example embodiments, the plurality of second lower semiconductor layers 142A may have substantially the same width in the first direction (X direction), but example embodiments are not limited thereto.

The plurality of second lower semiconductor layers 142A may include the semiconductor material. The plurality of second lower semiconductor layers 142A may include the semiconductor material different from that in the plurality of first lower semiconductor layers 145A. For example, the plurality of second lower semiconductor layers 142A may include silicon germanium (SiGe), and the plurality of first lower semiconductor layers 145A may include silicon (Si). However, example embodiments are not limited thereto, and as another example, the plurality of first lower semiconductor layers 145A and the plurality of second lower semiconductor layers 142A may include silicon germanium (SiGe). Here, a germanium (Ge) content (at %) in the plurality of first lower semiconductor layers 145A may be different from a germanium (Ge) content (at %) in the plurality of second lower semiconductor layers 142A. As an example, the germanium (Ge) content (at %) in the plurality of first lower semiconductor layers 145A may be less than the germanium (Ge) content (at %) in the plurality of second lower semiconductor layers 142A.

The plurality of second lower semiconductor layers 142A may have the first-type conductivity. The plurality of second lower semiconductor layers 142A may be doped with the first-type conductivity impurities. Here, the first-type conductivity may be the P-type conductivity, but example embodiments are not limited thereto. For example, the plurality of second lower semiconductor layers 142A may include boron (B), vanadium (V), indium (In), gallium (Ga), aluminum (Al), or the combination thereof. However, example embodiments are not limited thereto.

In some example embodiments, the plurality of second lower semiconductor layers 142A may have the same conductivity as the plurality of first lower semiconductor layers 145A. Here, the first-type conductivity impurities in the plurality of second lower semiconductor layers 142A may have a doping concentration greater than or substantially equal to a doping concentration of the first-type conductivity impurities in the plurality of first lower semiconductor layers 145A. The reason is that in a process of diffusing the impurities into the lower sheet structure 140A through heat treatment, the plurality of second lower semiconductor layers 142A include a material in which the impurities are diffused relatively well compared to the plurality of first lower semiconductor layers 145A.

FIGS. 2, 3, and 5 show two second lower semiconductor layers 142A and two first lower semiconductor layers 145A are alternately stacked, but example embodiments are not limited thereto. The number of the plurality of first lower semiconductor layers 145A and the plurality of second lower semiconductor layers 142A may be varied.

The upper sheet structure 140B may be disposed above the lower sheet structure 140A. The upper sheet structure 140B may be disposed on the PN junction structure 300 disposed on the lower sheet structure 140A, which is described below. In some example embodiments, the upper sheet structure 140B may have substantially the same width in the first direction (X direction) as a width of the lower sheet structure 140A in the first direction (X direction), but example embodiments are not limited thereto. The upper sheet structure 140B may completely overlap the lower sheet structure 140A in the third direction (Z direction), but example embodiments are not limited thereto. The upper sheet structure 140B may have second-type conductivity. The second-type conductivity may be N-type conductivity. For example, the upper sheet structure 140B may include phosphorus (P), antimony (Sb), arsenic (As), or a combination thereof. However, example embodiments are not limited thereto.

The upper sheet structure 140B according to some example embodiments may include a plurality of first upper semiconductor layers 145B and a plurality of second upper semiconductor layers 142B that are alternately stacked.

In some example embodiments, the plurality of first upper semiconductor layers 145B may have a structure, shape, and arrangement relationship similar to those of a plurality of upper channel patterns 240B of the transistor structure TS to be described below, and the plurality of second upper semiconductor layers 142B may have a structure, shape, and arrangement relationship similar to those of an upper sacrificial layer 220B (in FIG. 14) of the transistor structure TS to be described below.

The plurality of first upper semiconductor layers 145B may be disposed above the plurality of first lower semiconductor layers 145A. In detail, the plurality of first upper semiconductor layers 145B may be disposed on an upper surface of the PN junction structure 300 disposed on the plurality of first lower semiconductor layers 145A. The plurality of first upper semiconductor layers 145B may be spaced apart from the plurality of first lower semiconductor layers 145A in the third direction (Z direction). For example, the PN junction structure 300 may be disposed between the plurality of first upper semiconductor layers 145B and the plurality of first lower semiconductor layers 145A, and the plurality of first upper semiconductor layers 145B may be spaced apart from the plurality of first lower semiconductor layers 145A in the third direction (Z direction) due to the PN junction structure 300. The plurality of first lower semiconductor layers 145A may be spaced apart from each other in the third direction (Z direction).

In some example embodiments, the plurality of first upper semiconductor layers 145B may have substantially the same width in the first direction (X direction), but example embodiments are not limited thereto. For example, the plurality of first upper semiconductor layers 145B may have a width in the first direction (X direction) that is smaller as the upper semiconductor layer 145B gets farther from the upper surface of the base insulating layer 100.

The plurality of first upper semiconductor layers 145B may include the semiconductor material. The plurality of first upper semiconductor layers 145B may include the same material as the plurality of first lower semiconductor layers 145A. For example, the plurality of first upper semiconductor layers 145B may include the elemental semiconductor material, such as silicon (Si) or germanium (Ge). However, example embodiments are not limited thereto. The plurality of first upper semiconductor layers 145B may be formed by etching a portion of the substrate 101 (in FIG. 14), or may include the epitaxial layer grown from the substrate 101 (in FIG. 14). As an example, the plurality of first upper semiconductor layers 145B may include silicon (Si).

The plurality of first upper semiconductor layers 145B may have the second-type conductivity. That is, the plurality of first upper semiconductor layers 145B may be doped with second-type conductivity impurities. Here, the second-type conductivity may be the N-type conductivity, but example embodiments are not limited thereto. The plurality of first upper semiconductor layers 145B may have different type of conductivity than the plurality of first lower semiconductor layers 145A. For example, the plurality of first upper semiconductor layers 145B may include phosphorus (P), antimony (Sb), arsenic (As), or the combination thereof. However, example embodiments are not limited thereto.

The plurality of second upper semiconductor layers 142B may be disposed above the lower sheet structure 140A. The plurality of second upper semiconductor layers 142B may be stacked while being spaced apart from each other in the third direction (Z direction). The plurality of first upper semiconductor layers 145B may be disposed between the plurality of plurality of second upper semiconductor layers 142B stacked while being spaced apart from each other in the third direction (Z direction). That is, the plurality of first upper semiconductor layers 145B and the plurality of second upper semiconductor layers 142B may be alternately stacked in the third direction (Z direction). In some example embodiments, the plurality of second upper semiconductor layers 142B may have substantially the same width in the first direction (X direction), but example embodiments are not limited thereto.

The plurality of second upper semiconductor layers 142B may include the semiconductor material. The plurality of second upper semiconductor layers 142B may include the same material as the plurality of second lower semiconductor layers 142A. The plurality of second upper semiconductor layers 142B may include the semiconductor material different from that in the plurality of first upper semiconductor layers 145B. For example, the plurality of second upper semiconductor layers 142B may include silicon germanium (SiGe), and the plurality of first upper semiconductor layers 145B may include silicon (Si). However, example embodiments are not limited thereto, and as another example, the plurality of first upper semiconductor layers 145B and the plurality of second upper semiconductor layers 142B may include silicon germanium (SiGe). Here, a germanium (Ge) content (at %) in the plurality of first upper semiconductor layers 145B may be different from a germanium (Ge) content (at %) in the plurality of second upper semiconductor layers 142B. As an example, the germanium (Ge) content (at %) in the plurality of first upper semiconductor layers 145B may be less than the germanium (Ge) content (at %) in the plurality of second upper semiconductor layers 142B.

The plurality of second upper semiconductor layers 142B may have the second-type conductivity. The plurality of second upper semiconductor layers 142B may be doped with the second-type conductivity impurities. Here, the second-type conductivity may be the N-type conductivity, but example embodiments are not limited thereto. For example, the plurality of second upper semiconductor layers 142B may include phosphorus (P), antimony (Sb), arsenic (As), or the combination thereof. However, example embodiments are not limited thereto.

In some example embodiments, the plurality of second upper semiconductor layers 142B may have the same conductivity as the plurality of first upper semiconductor layers 145B. Here, the second-type conductivity impurities in the plurality of second upper semiconductor layers 142B may have a doping concentration greater than or substantially equal to a doping concentration of the second-type conductivity impurities in the plurality of first upper semiconductor layers 145B. The reason is that in a process of diffusing the impurities into the upper sheet structure 140B through the heat treatment, the plurality of second upper semiconductor layers 142B includes a material in which the impurities are diffused relatively well compared to the plurality of first upper semiconductor layers 145B.

The stacked structure SS of the semiconductor device according to some example embodiments may further include a field insulating layer 105 disposed on the base insulating layer 100.

The field insulating layer 105 may be disposed on the base insulating layer 100. The field insulating layer 105 may cover at least a portion of a side surface of the protruding pattern 110. For example, as shown in FIG. 3, the field insulating layer 105 may cover a portion of the side surface of the protruding pattern 110. That is, the side surface of the protruding pattern 110 may have a portion covered by the field insulating layer 105 and the remaining portion covered by a dummy main gate structure 160M to be described below. The field insulating layer 105 may overlap the protruding pattern 110 in the second direction (Y direction). In addition, the field insulating layer 105 may not be disposed on the upper surface of the protruding pattern 110.

FIG. 3 shows that the field insulating layer 105 covers at least a portion of the side surface of the protruding pattern 110, but example embodiments are not limited thereto. For example, the field insulating layer 105 may entirely cover the side surface of the protruding pattern 110.

The field insulating layer 105 may include, for example, oxide, nitride, oxynitride, or a combination film thereof. The field insulating layer 105 is shown as a single film, which is only for the convenience of description, and example embodiments are not limited thereto.

The lower semiconductor pattern 150A may be disposed on at least one side of the lower sheet structure 140A. For example, the lower semiconductor pattern 150A may be disposed on each of two sides of the lower sheet structure 140A in the first direction (X direction). The lower semiconductor pattern 150A may be disposed on the protruding pattern 110. The lower semiconductor pattern 150A may be in contact with a side surface of the lower sheet structure 140A and the upper surface of the protruding pattern 110. The lower semiconductor pattern 150A may be electrically connected to the lower sheet structure 140A.

In some example embodiments, at least a portion of the lower semiconductor pattern 150A may be surrounded by the protruding pattern 110. An upper surface of the lower semiconductor pattern 150A may be disposed at substantially the same level as an upper surface of the lower sheet structure 140A. The lower semiconductor pattern 150A in the third direction (Z direction) may have a length greater than or substantially equal to a length of the lower sheet structure 140A in the third direction (Z direction). A lower surface of the lower semiconductor pattern 150A may be closer to the upper surface of the base insulating layer 100 than to a lower surface of the lower sheet structure 140A.

The lower semiconductor pattern 150A may be an epitaxial pattern formed by a selective epitaxial growth process using the plurality of first lower semiconductor layers 145A and an active pattern 111 (in FIG. 14) as its seeds. In some example embodiments, the lower semiconductor pattern 150A may include the semiconductor material. The lower semiconductor pattern 150A may have the first-type conductivity. The lower semiconductor pattern 150A may be doped with the first-type conductivity impurities. Here, the first-type conductivity may be the P-type conductivity, but example embodiments are not limited thereto. For example, the lower semiconductor pattern 150A may include boron (B), vanadium (V), indium (In), gallium (Ga), aluminum (Al), or the combination thereof. However, example embodiments are not limited thereto.

In some example embodiments, the lower semiconductor pattern 150A may have the same conductivity as the lower sheet structure 140A. Here, the first-type conductivity impurities in the lower semiconductor pattern 150A may have a doping concentration greater than or substantially equal to a doping concentration of the first-type conductivity impurities in the lower sheet structure 140A.

The lower semiconductor pattern 150A of the semiconductor device according to some example embodiments may include a first sub-lower pattern 151A and a second sub-lower pattern 152A.

The first sub-lower pattern 151A may be disposed on the side surface of the lower sheet structure 140A and the upper surface of the protruding pattern 110. The first sub-lower pattern 151A may be in contact with the lower sheet structure 140A and the protruding pattern 110. The first sub-lower pattern 151A may include the semiconductor material. For example, the first sub-lower pattern 151A may include silicon (Si) or silicon germanium (SiGe), which is the semiconductor material. However, example embodiments are not limited thereto.

The second sub-lower pattern 152A may be disposed on the first sub-lower pattern 151A. The second sub-lower pattern 152A may be surrounded by the first sub-lower pattern 151A. An upper surface of the second sub-lower pattern 152A may be disposed at substantially the same level as an upper surface of the first sub-lower pattern 151A. That is, the upper surface of the second sub-lower pattern 152A may be disposed at substantially the same distance from the upper surface of the first sub-lower pattern 151A and the upper surface of the base insulating layer 100, but example embodiments are not limited thereto.

The second sub-lower pattern 152A may include the semiconductor material. For example, the second sub-lower pattern 152A may include the same material as the first sub-lower pattern 151A. As an example, the first sub-lower pattern 151A and the second sub-lower pattern 152A may include silicon (Si) or silicon germanium (SiGe), which is the semiconductor material, but example embodiments are not limited thereto.

In some example embodiments, the first sub-lower pattern 151A and the second sub-lower pattern 152A may have the first-type conductivity. The first sub-lower pattern 151A and the second sub-lower pattern 152A may be doped with first-type conductivity impurities. Here, the first-type conductivity may be the P-type conductivity. For example, the first sub-lower pattern 151A and the second sub-lower pattern 152A may include boron (B), vanadium (V), indium (In), gallium (Ga), aluminum (Al), or the combination thereof. However, example embodiments are not limited thereto. Here, types of the impurities included in the first sub-lower pattern 151A may be the same as or different from types of the impurities included in the second sub-lower pattern 152A. In addition, the impurities doped in the first sub-lower pattern 151A may have a doping concentration different from a doping concentration of the impurities doped in the second sub-lower pattern 152A. For example, the first-type conductivity impurities in the second sub-lower pattern 152A may have the doping concentration greater than the doping concentration of the first-type conductivity impurities in the first sub-lower pattern 151A, but example embodiments are not limited thereto. However, example embodiments are not limited thereto, and as another example, the first sub-lower pattern 151A and the second sub-lower pattern 152A may have the second-type conductivity.

In some example embodiments, the impurities in the first sub-lower pattern 151A and the impurities in the second sub-lower pattern 152A may each have the doping concentration greater than or substantially equal to a doping concentration of the impurities in the lower sheet structure 140A. For example, the impurities in the first sub-lower pattern 151A may have the doping concentration greater than or substantially equal to the doping concentration of the impurities in the plurality of first lower semiconductor layers 145A and the doping concentration of the impurities in the plurality of second lower semiconductor layers 142A. In addition, the impurities in the second sub-lower pattern 152A may have the doping concentration greater than or substantially equal to the doping concentration of the impurities in the plurality of first lower semiconductor layers 145A and the doping concentration of the impurities in the plurality of second lower semiconductor layers 142A. This doping concentration may result from a process feature in which the impurities of the first-type conductivity, present in the lower semiconductor pattern 150A, are diffused into the lower sheet structure 140A through a heat treatment process.

In some example embodiments, the lower semiconductor pattern 150A is described as being formed of a double layer, but example embodiments are not limited thereto. The lower semiconductor pattern 150A may be formed of a single layer including the semiconductor material, or may be formed of three or more layers.

The upper semiconductor pattern 150B may be disposed above the lower semiconductor pattern 150A. The upper semiconductor pattern 150B may be spaced apart from the lower semiconductor pattern 150A in the third direction (Z direction). For example, a barrier structure 170 may be disposed between the upper semiconductor pattern 150B and the lower semiconductor pattern 150A, and the upper semiconductor pattern 150B and the lower semiconductor pattern 150A may be spaced apart from each other in the third direction (Z direction) due to the barrier structure 170.

The upper semiconductor pattern 150B may be disposed on at least one side of the upper sheet structure 140B. For example, the upper semiconductor pattern 150B may be disposed on each of two sides of the upper sheet structure 140B in the first direction (X direction). The upper semiconductor pattern 150B may be in contact with a side surface of the upper sheet structure 140B and an upper surface 170_U of the barrier structure 170 to be described below. At least a portion of a side surface of the upper semiconductor pattern 150B may be in contact with the PN junction structure 300 to be described below. The upper semiconductor pattern 150B may overlap the PN junction structure 300 to be described below in the first direction (X direction). The upper semiconductor pattern 150B may not be in contact with the upper surface of the protruding pattern 110. The upper semiconductor pattern 150B may be electrically connected to the upper sheet structure 140B.

The upper semiconductor pattern 150B may be an epitaxial pattern formed by a selective epitaxial growth process using the plurality of first upper semiconductor layers 145B as its seeds. Here, the upper semiconductor pattern 150B may be a pattern formed using only side surfaces of the plurality of first upper semiconductor layers 145B as its seeds. That is, unlike the lower semiconductor pattern 150A, which is the pattern formed using the upper surface of the active pattern 111 (in FIG. 14) and side surfaces of the plurality of first lower semiconductor layers 145A as its seeds, the upper semiconductor pattern 150B may be a pattern formed using only the side surfaces of the plurality of first upper semiconductor layers 145B as its seeds.

In some example embodiments, an upper surface of the upper semiconductor pattern 150B may be disposed at substantially the same level as an upper surface of the upper sheet structure 140B. That is, the upper surface of the upper semiconductor pattern 150B may have substantially the same distance from the upper surface of the upper sheet structure 140B and the upper surface of the base insulating layer 100, but example embodiments are not limited thereto.

In some example embodiments, a lower surface of the upper semiconductor pattern 150B may be disposed at a lower level than a lower surface of the upper sheet structure 140B. That is, the lower surface of the upper semiconductor pattern 150B may be closer to the upper surface of the lower sheet structure 140A than to the lower surface of the upper sheet structure 140B. Accordingly, the lower surface of the upper semiconductor pattern 150B may be disposed at a lower level than a lower surface of the PN junction structure 300. That is, the lower surface of the upper semiconductor pattern 150B may be closer to the upper surface of the lower sheet structure 140A than to the lower surface of the PN junction structure 300. Accordingly, at least a portion of the upper semiconductor pattern 150B may overlap the PN junction structure 300 disposed between the upper sheet structure 140B and the lower sheet structure 140A in the first direction (X direction). At least a portion of the upper semiconductor pattern 150B may be in contact with the PN junction structure 300.

In some example embodiments, the upper semiconductor pattern 150B may include the semiconductor material. The upper semiconductor pattern 150B may have the second-type conductivity. The upper semiconductor pattern 150B may be doped with the second-type conductivity impurities. Here, the second-type conductivity may be the N-type conductivity, but example embodiments are not limited thereto. For example, the upper semiconductor pattern 150B may include phosphorus (P), antimony (Sb), arsenic (As), or the combination thereof. However, example embodiments are not limited thereto.

In some example embodiments, the upper semiconductor pattern 150B may have the same conductivity as the upper sheet structure 140B. Here, the second-type conductivity impurities in the upper semiconductor pattern 150B may have a doping concentration greater than or substantially equal to a doping concentration of the second-type conductivity impurities in the upper sheet structure 140B.

The upper semiconductor pattern 150B of the semiconductor device according to some example embodiments may include a first sub-upper pattern 151B and a second sub-upper pattern 152B.

The first sub-upper pattern 151B may be disposed on the side surface of the upper sheet structure 140B. The first sub-upper pattern 151B may be in contact with the plurality of first upper semiconductor layers 145B. In some example embodiments, the first sub-upper pattern 151B may not be disposed on the upper surface of the barrier structure 170, which is described below. This feature may result from a process feature in which the first sub-upper pattern 151B uses the plurality of first upper semiconductor layers 145B as its seeds rather than using the barrier structure 170 as its seeds. In some example embodiments, the first sub-upper pattern 151B may be in contact with the upper sheet structure 140B. For example, the first sub-upper pattern 151B may overlap the plurality of first upper semiconductor layers 145B and the plurality of second upper semiconductor layers 142B in the first direction (X direction).

In some example embodiments, the first sub-upper pattern 151B may protrude from the side surface of the upper sheet structure 140B. For example, a side surface of the first sub-upper pattern 151B may include a curved surface protruding convexly from the side surface of the upper sheet structure 140B. Accordingly, the first sub-upper pattern 151B may have a width in the first direction (X direction) that is increased as the first sub-upper pattern 151B gets farther from the lower surface of the lower sheet structure 140A and then reduced. The first sub-upper pattern 151B may include the semiconductor material. For example, the first sub-upper pattern 151B may include silicon (Si) or silicon germanium (SiGe), which is the semiconductor material. However, example embodiments are not limited thereto.

The second sub-upper pattern 152B may be disposed on the side surface of the first sub-upper pattern 151B. The second sub-upper pattern 152B may be disposed on the barrier structure 170 to be described below. Accordingly, the second sub-upper pattern 152B may be spaced apart from the lower semiconductor pattern 150A in the third direction (Z direction) due to the barrier structure 170. The second sub-upper pattern 152B may be in contact with the side surface of the first sub-upper pattern 151B. The first sub-upper pattern 151B may be disposed between the second sub-upper pattern 152B and the upper sheet structure 140B, the second sub-upper pattern 152B may thus be in non-contact with the upper sheet structure 140B, but example embodiments are not limited thereto.

The second sub-upper pattern 152B may include the semiconductor material. For example, the second sub-upper pattern 152B may include the same material as the first sub-upper pattern 151B. As an example, the first sub-upper pattern 151B and the second sub-upper pattern 152B may include silicon (Si) or silicon germanium (SiGe), which is the semiconductor material, but example embodiments are not limited thereto.

In some example embodiments, the first sub-upper pattern 151B and the second sub-upper pattern 152B may have the second-type conductivity. The first sub-upper pattern 151B and the second sub-upper pattern 152B may be doped with the second-type conductivity impurities. The second-type conductivity may be the N-type conductivity. For example, the first sub-upper pattern 151B and the second sub-upper pattern 152B may include phosphorus (P), antimony (Sb), arsenic (As), or the combination thereof. However, example embodiments are not limited thereto. Here, types of the impurities included in the first sub-upper pattern 151B may be the same as or different from types of the impurities included in the second sub-upper pattern 152B. In addition, a doping concentration of the impurities doped in the first sub-upper pattern 151B may be different from a doping concentration of the impurities doped in the second sub-upper pattern 152B. For example, the first-type conductivity impurities in the second sub-upper pattern 152B may have the doping concentration greater than the doping concentration of the first-type conductivity impurities in the first sub-upper pattern 151B, but example embodiments are not limited thereto. However, example embodiments are not limited thereto, and as another example, the first sub-upper pattern 151B and the second sub-upper pattern 152B may have the first-type conductivity.

In some example embodiments, the impurities in the first sub-upper pattern 151B and the impurities in the second sub-upper pattern 152B may each have the doping concentration greater than or substantially equal to the doping concentration of the impurities in the upper sheet structure 140B. For example, the impurities in the first sub-upper pattern 151B may have the doping concentration greater than or substantially equal to the doping concentration of the impurities in the plurality of first upper semiconductor layers 145B and the doping concentration of the impurities in the plurality of second upper semiconductor layers 142B. In addition, the impurities in the second sub-upper pattern 152B may have the doping concentration greater than or substantially equal to the doping concentration of the impurities in the plurality of first upper semiconductor layers 145B and the doping concentration of the impurities in the plurality of second upper semiconductor layers 142B.

In some example embodiments, the upper semiconductor pattern 150B is described as being formed of a double layer, but example embodiments are not limited thereto. The upper semiconductor pattern 150B may be formed of a single layer including the semiconductor material, or may be formed of three or more layers.

The stacked structure SS of the semiconductor device according to some example embodiments may further include the barrier structure 170 disposed between the lower semiconductor pattern 150A and the upper semiconductor pattern 150B.

The barrier structure 170 may be disposed between the lower semiconductor pattern 150A and the upper semiconductor pattern 150B. The barrier structure 170 may overlap the lower semiconductor pattern 150A and the upper semiconductor pattern 150B in the third direction (Z direction). The barrier structure 170 may be disposed on the side surface of the PN junction structure 300 to be described below.

The barrier structure 170 may include a first liner 171 extending along the side surface of the PN junction structure 300 to be described below and the upper surface of the lower semiconductor pattern 150A, and a barrier pattern 172 disposed on the first liner 171.

The first liner 171 and the barrier pattern 172 may include various insulating materials. The first liner 171 and the barrier pattern 172 may include different materials, but example embodiments are not limited thereto. For example, the first liner 171 may include silicon nitride, silicon oxynitride, or a combination thereof, and the barrier pattern 172 may include silicon oxide, silicon nitride, silicon oxynitride, or a combination thereof. However, example embodiments are not limited thereto. The barrier structure 170 may allow the lower semiconductor pattern 150A and the upper semiconductor pattern 150B to be spaced apart from each other in the third direction (Z direction).

The PN junction structure 300 may be disposed on the lower sheet structure 140A. The PN junction structure 300 may be disposed between the lower sheet structure 140A and the upper sheet structure 140B. The PN junction structure 300 may be disposed between the uppermost first lower semiconductor layer 145A and the lowermost first upper semiconductor layer 145B. The PN junction structure 300 may be in contact with the uppermost first lower semiconductor layer 145A and the lowermost first upper semiconductor layer 145B. However, example embodiments are not limited thereto, and as another example, the PN junction structure 300 may be in contact with the uppermost second lower semiconductor layer 142A and the lowermost second upper semiconductor layer 142B.

The PN junction structure 300 may overlap the barrier structure 170 in the first direction (X direction). The side surface of the PN junction structure 300 may be in contact with the barrier structure 170, but example embodiments are not limited thereto. In addition, at least a portion of the PN junction structure 300 may overlap the upper semiconductor pattern 150B in the first direction (X direction). The side surface of the PN junction structure 300 may be in contact with the upper semiconductor pattern 150B, but example embodiments are not limited thereto. Accordingly, in a process of forming the PN junction structure 300 through the heat treatment, the impurities may be easily diffused into the PN junction structure 300.

In some example embodiments, a thickness of the PN junction structure 300 in the third direction (Z direction) may be greater than a thickness of the barrier structure 170 in the third direction (Z direction). In some example embodiments, the upper surface of the PN junction structure 300 may be disposed at a higher level than the lower surface of the upper semiconductor pattern 150B. That is, the upper surface of the PN junction structure 300 may be farther from the upper surface of the lower sheet structure 140A than from the lower surface of the upper semiconductor pattern 150B. In other words, the upper surface of the PN junction structure 300 may be farther from the upper surface of the lower sheet structure 140A than from the upper surface 170_U of the barrier structure 170.

The PN junction structure 300 may include the semiconductor material. The PN junction structure 300 may include the material different from those in the plurality of first lower semiconductor layers 145A and the plurality of first upper semiconductor layers 145B. For example, the PN junction structure 300 may include silicon germanium (SiGe). In some example embodiments, the PN junction structure 300, the plurality of second lower semiconductor layers 142A, and the plurality of second upper semiconductor layers 142B may include silicon germanium (SiGe), and the plurality of first lower semiconductor layers 145A and the plurality of first upper semiconductor layers 145B may include silicon (Si). However, example embodiments are not limited thereto.

Here, a germanium (Ge) content (at %) in the PN junction structure 300 may be different from a germanium (Ge) content (at %) in the plurality of second lower semiconductor layers 142A and the germanium (Ge) content (at %) in the plurality of second upper semiconductor layers 142B. For example, the germanium (Ge) content (at %) in the PN junction structure 300 may be greater than the germanium (Ge) content (at %) in the plurality of second lower semiconductor layers 142A and the germanium (Ge) content (at %) in the plurality of second upper semiconductor layers 142B, but example embodiments are not limited thereto.

In some example embodiments, in a process of removing a preliminary intermediate insulating structure 220P (in FIG. 14) and forming an intermediate insulating structure 220 in a space where the preliminary intermediate insulating structure 220P is removed, the preliminary intermediate insulating structure (220P in FIG. 14) may be selectively etched with respect to the lower sacrificial layer 220A (in FIG. 14) and upper sacrificial layer 220B (in FIG. 14) of the transistor structure TS to be described below. As an example, a germanium (Ge) content (at %) in the preliminary intermediate insulating structure 220P (in FIG. 14) may be greater than a germanium (Ge) content (at %) in the lower sacrificial layer 220A (in FIG. 14) and a germanium (Ge) content (at %) in the upper sacrificial layer 220B (in FIG. 14) of the transistor structure TS to be described below.

Meanwhile, the lower sacrificial layer 220A (in FIG. 14) or upper sacrificial layer 220B (in FIG. 14) of the transistor structure TS to be described below may be simultaneously formed by the same process as each of the plurality of second lower semiconductor layers 142A or the plurality of second upper semiconductor layers 142B, and the lower sacrificial layer 220A or the upper sacrificial layer 220B may include the same material as that in the semiconductor layer 142A or 142B. Therefore, the germanium (Ge) content (at %) in the PN junction structure 300 may be different from the germanium (Ge) content (at %) in the plurality of second lower semiconductor layers 142A and the germanium (Ge) content (at %) in the plurality of second upper semiconductor layers 142B. However, example embodiments are not limited thereto, and the PN junction structure 300 may be variously modified within a range where the PN junction structure 300 includes the different material from those in the plurality of first lower semiconductor layers 145A and the plurality of first upper semiconductor layers 145B.

The PN junction structure 300 of the semiconductor device according to some example embodiments may include a first doped layer 320 having the first-type conductivity and disposed on the lower sheet structure 140A, and a second doped layer 310 having the second-type conductivity and disposed on the first doped layer 320.

The first doped layer 320 may be disposed on the lower sheet structure 140A. For example, the first doped layer 320 may be disposed directly on an upper surface of the uppermost first lower semiconductor layer 145A, but example embodiments are not limited thereto. As another example, the first doped layer 320 may be disposed directly on an upper surface of the uppermost second lower semiconductor layer 142A.

The first doped layer 320 may be disposed on a side surface of the barrier structure 170. The first doped layer 320 may be disposed between the barrier structures 170, which are arranged to be spaced apart from each other in the first direction (X direction). The first doped layer 320 may overlap the barrier structure 170 in the first direction (X direction). A lower surface of the first doped layer 320 may be disposed at substantially the same level as the upper surface of the lower semiconductor pattern 150A. That is, the lower surface of the first doped layer 320 may be disposed at substantially the same distance from the upper surface of the lower semiconductor pattern 150A and the upper surface of the base insulating layer 100. The lower surface of the first doped layer 320 may be aligned with a lower surface of the barrier structure 170, but example embodiments are not limited thereto. In some example embodiments, the first doped layer 320 may not overlap the lower semiconductor pattern 150A and the upper semiconductor pattern 150B in the first direction (X direction), but example embodiments are not limited thereto.

An upper surface of the first doped layer 320 may be disposed at a lower level than the upper surface 170_U of the barrier structure 170. That is, the upper surface of the first doped layer 320 may be at a level closer to the upper surface of the lower sheet structure 140A in a third direction (Z direction) than to a level of the upper surface 170_U of the barrier structure 170 in a third direction (Z direction). In addition, the upper surface of the first doped layer 320 may be closer to the upper surface of the lower sheet structure 140A than to the lower surface of the upper semiconductor pattern 150B.

The first doped layer 320 may have the first-type conductivity. The first doped layer 320 may be doped with the first-type conductivity impurities. Here, the first-type conductivity may be the P-type conductivity. For example, the first doped layer 320 may include boron (B), vanadium (V), indium (In), gallium (Ga), aluminum (Al), or the combination thereof. However, example embodiments are not limited thereto.

In some example embodiments, the impurities in the first doped layer 320 may have a doping concentration less than or substantially equal to the doping concentration of the impurities in the lower sheet structure 140A. For example, the impurities in the first doped layer 320 may have the doping concentration less than or substantially equal to the doping concentration of the impurities in the plurality of first lower semiconductor layers 145A and the doping concentration of the impurities in the plurality of second lower semiconductor layers 142A.

In addition, the impurities in the first doped layer 320 may have the doping concentration less than or substantially equal to a doping concentration of the impurities in the lower semiconductor pattern 150A. For example, the impurities in the first doped layer 320 may have the doping concentration less than or substantially equal to the doping concentration of the impurities in the first sub-lower pattern 151A and the doping concentration of the impurities in the second sub-lower pattern 152A. This doping concentration may result from a process feature in which the impurities present in the lower semiconductor pattern 150A are diffused into the first doped layer 320 through the heat treatment process. As an example, the doping concentration of the impurities in the first doped layer 320 may be 1×10¹⁷ cm⁻³ to 1×10¹⁹ cm⁻³, but example embodiments are not limited thereto.

The second doped layer 310 may be disposed on the first doped layer 320. The second doped layer 310 may be disposed between the first doped layer 320 and the upper sheet structure 140B. For example, the second doped layer 310 may be disposed between the first doped layer 320 and the lowermost first upper semiconductor layer 145B. The second doped layer 310 may be in contact with the first doped layer 320 and the first upper semiconductor layer 145B, but example embodiments are not limited thereto. As another example, the second doped layer 310 may be in contact with the second upper semiconductor layer 142B.

The second doped layer 310 may be disposed on the side surface of the upper semiconductor pattern 150B and the side surface of the barrier structure 170. The second doped layer 310 may overlap the upper semiconductor pattern 150B and the barrier structure 170 in the first direction (X direction). A side surface of the second doped layer 310 may be in contact with the upper semiconductor pattern 150B and the barrier structure 170. Accordingly, at least a portion of the second doped layer 310 may be in contact with the upper semiconductor pattern 150B, and the impurities present in the upper semiconductor pattern 150B may thus be easily diffused into the second doped layer 310 through the heat treatment process.

An upper surface 310_U of the second doped layer 310 may be disposed at a higher level than the lower surface of the upper semiconductor pattern 150B. That is, the upper surface 310_U of the second doped layer 310 may be farther from the upper surface of the lower sheet structure 140A than from the upper surface of the upper semiconductor pattern 150B. In addition, the upper surface of the second doped layer 310 may be farther from the upper surface of the lower sheet structure 140A than from the upper surface 170_U of the barrier structure 170.

In some example embodiments, the second doped layer 310 may include the same semiconductor material as the first doped layer 320. For example, the first doped layer 320 and the second doped layer 310 may include silicon germanium (SiGe), but example embodiments are not limited thereto. Here, a germanium (Ge) content (at %) in the first doped layer 320 may be substantially the same as a germanium (Ge) content (at %) in the second doped layer 310. This content may result from a process feature in which the PN junction structure 300 is formed by doping a portion of the preliminary intermediate insulating structure 220P (in FIG. 14) with the first-type conductivity impurities and doping the remaining portion with the second-type conductivity impurities through the heat treatment process.

The second doped layer 310 may have the second-type conductivity. The second doped layer 310 may be doped with the second-type conductivity impurities. Here, the second-type conductivity may be the N-type conductivity. For example, the second doped layer 310 may include phosphorus (P), antimony (Sb), arsenic (As), or the combination thereof. However, example embodiments are not limited thereto.

In some example embodiments, the impurities in the second doped layer 310 may have a doping concentration less than or substantially equal to the doping concentration of the impurities in the upper sheet structure 140B. For example, the impurities in the second doped layer 310 may have the doping concentration less than or substantially equal to the doping concentration of the impurities in the plurality of first upper semiconductor layers 145B and the doping concentration of the impurities in the plurality of second upper semiconductor layers 142B.

In addition, the impurities in the second doped layer 310 may have the doping concentration less than or substantially equal to the doping concentration of the impurities in the upper semiconductor pattern 150B. For example, the impurities in the second doped layer 310 may have the doping concentration less than or substantially equal to a doping concentration of the impurities in the first sub-upper pattern 151B and a doping concentration of the impurities in the second sub-upper pattern 152B. This concentration may result from a process feature in which the impurities present in the upper semiconductor pattern 150B, are diffused into the second doped layer 310 through the heat treatment process. As an example, the doping concentration of the impurities in the second doped layer 310 may be 1×10¹⁷ cm⁻³ to 1×10¹⁹ cm⁻³, but example embodiments are not limited thereto.

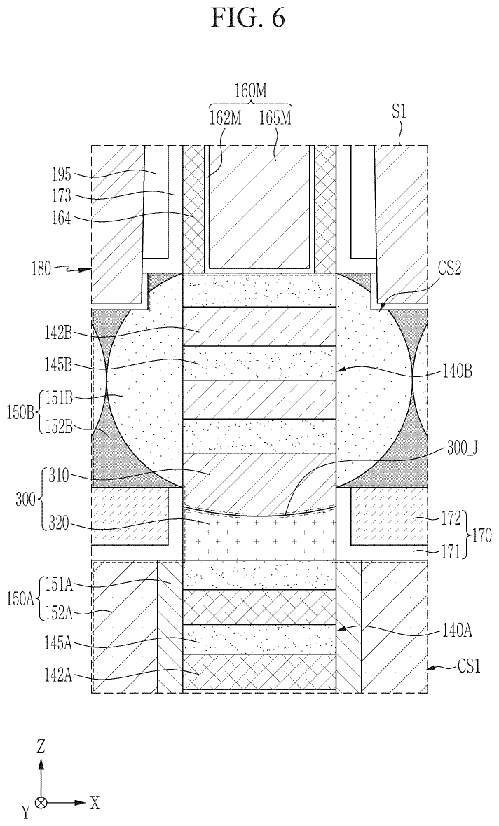

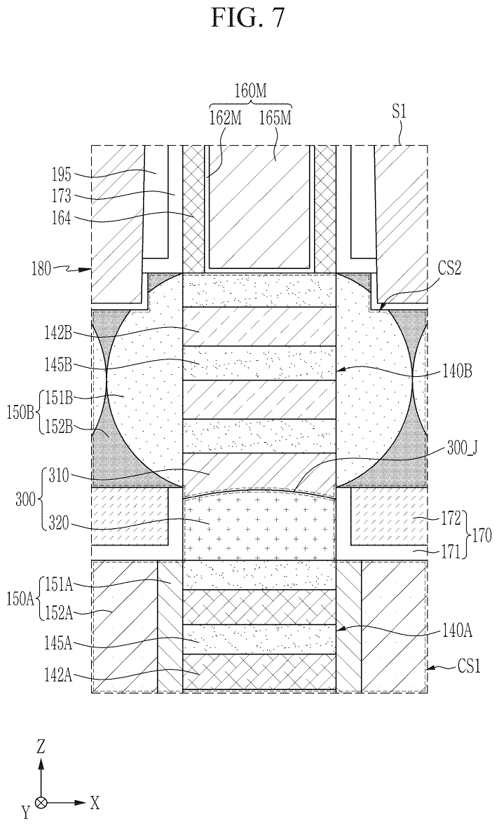

In some example embodiments, the first doped layer 320 and the second doped layer 310 may form a PN junction interface 300_J. The PN junction interface 300_J may be defined as the upper surface of the first doped layer 320 and a lower surface of the second doped layer 310 that are joined to each other. The upper surface of the first doped layer 320 may have a complementary shape to the lower surface of the second doped layer 310. The PN junction interface 300_J may be flat on a cross section in a first-third direction (X-Z direction), but example embodiments are not limited thereto. That is, the upper surface of the first doped layer 320 and the lower surface of the second doped layer 310 may be flat, but example embodiments are not limited thereto. This configuration is described below with reference to FIGS. 6 and 7.

In summary, the lower semiconductor pattern 150A, lower sheet structure 140A, and first doped layer 320 of the semiconductor device according to some example embodiments may have the first-type conductivity, and upper semiconductor pattern 150B, upper sheet structure 140B, and the second doped layer 310 thereof may have the second-type conductivity. Accordingly, the lower semiconductor pattern 150A, lower sheet structure 140A, and first doped layer 320 of the semiconductor device according to some example embodiments may form a first-type conductivity doped region CS1, and the upper semiconductor pattern 150B, upper sheet structure 140B, and second doped layer 310 thereof may form a second-type conductivity doped region CS2. The first-type conductivity doped region CS1 may have a different type of conductivity from that of the second-type conductivity doped region CS2, and the first doped layer 320 and the second doped layer 310 may form the PN junction interface 300_J. Therefore, the stacked structure SS of the semiconductor device according to some example embodiments may perform a diode function.

In some example embodiments, the PN junction structure 300 is described as including the first doped layer 320 and the second doped layer 310, but example embodiments are not limited thereto. For example, the PN junction structure 300 may include three or more layers. Here, a portion of the PN junction structure 300 may have the first-type conductivity, and the remaining portion thereof may have the second-type conductivity, thus forming the PN junction interface 300_J.

The stacked structure SS of the semiconductor device according to some example embodiments may further include the dummy main gate structure 160M disposed on the upper sheet structure 140B.

The dummy main gate structure 160M may extend in the second direction (Y direction). The dummy main gate structure 160M may intersect the protruding pattern 110. In some example embodiments, the dummy main gate structure 160M may float. For example, the dummy main gate structure 160M may not be electrically connected to a gate structure 260 of the transistor structure TS.

As shown in FIG. 3, the dummy main gate structure 160M may be disposed on the uppermost first upper semiconductor layer 145B. The dummy main gate structure 160M may be disposed on the side surface of the upper sheet structure 140B in the second direction (Y direction) and the side surface of the lower sheet structure 140A in the second direction (Y direction). The dummy main gate structure 160M may be disposed on the field insulating layer 105. The dummy main gate structure 160M may be disposed on the side surface of the PN junction structure 300 in the second direction (Y direction).

The dummy main gate structure 160M may include a dummy main gate electrode 165M and a dummy main gate insulating film 162M.

The dummy main gate electrode 165M may be disposed on the upper sheet structure 140B. As shown in FIG. 3, the dummy main gate electrode 165M may be disposed on the uppermost first upper semiconductor layer 145B. The dummy main gate electrode 165M may be disposed on the side surface of the upper sheet structure 140B in the second direction (Y direction) and the side surface of the lower sheet structure 140A in the second direction (Y direction). The dummy main gate electrode 165M may be disposed on the field insulating layer 105. The dummy main gate electrode 165M may be disposed on the side surface of the PN junction structure 300 in the second direction (Y direction).

The dummy main gate electrode 165M may include a conductive material. For example, the dummy main gate electrode 165M may include at least one of a metal, a metal alloy, a conductive metal nitride, a metal silicide, a doped semiconductor material, a conductive metal oxide, and a conductive metal oxynitride. However, example embodiments are not limited thereto.

As shown in FIGS. 2 and 5, the dummy main gate insulating film 162M may extend along a side surface of the dummy main gate electrode 165M. The dummy main gate insulating film 162M may be disposed between the dummy main gate electrode 165M and a spacer 164 to be described below and between the dummy main gate electrode 165M and the upper sheet structure 140B.

As shown in FIG. 3, the dummy main gate insulating film 162M may be disposed between the dummy main gate electrode 165M and the upper sheet structure 140B, between the dummy main gate electrode 165M and the PN junction structure 300, between the dummy main gate electrode 165M and the lower sheet structure 140A, and between the dummy main gate electrode 165M and the field insulating layer 105. The dummy main gate insulating film 162M may include the various insulating materials.

In some example embodiments, the dummy main gate insulating film 162M is shown as a single film, but example embodiments are not limited thereto. For example, the dummy main gate insulating film 162M may be formed of a multilayer film including silicon oxide (SiO₂) and a high-k material. Here, the high-k material may include a material having a higher dielectric constant than silicon oxide (SiO₂), such as hafnium oxide (HfO), aluminum oxide (AlO), or tantalum oxide (TaO). However, example embodiments are not limited thereto.

The semiconductor device according to some example embodiments may further include the spacer 164 and a capping layer 166.

The spacer 164 may be disposed on the side surface of the dummy main gate electrode 165M. The spacer 164 may include, for example, at least one of silicon nitride (SiN), silicon oxynitride (SiON), silicon oxide (SiO₂), silicon carbonitride (SiOCN), silicon boron nitride (SiBN), silicon oxyboron nitride (SiOBN), silicon oxycarbide (SiOC), and a combination thereof. However, example embodiments are not limited thereto. The spacer 164 is shown as a single film, which is only for the convenience of description, but example embodiments are not limited thereto.

The capping layer 166 may be disposed on the dummy main gate structure 160M. The capping layer 166 may be disposed on a side surface of the spacer 164. An upper surface of the capping layer 166 may be coplanar (and/or substantially coplanar) with an upper surface of an interlayer insulating layer 195. Unlike what is shown in the drawing, the capping layer 166 may also be disposed on the dummy main gate structure 160M and the spacer 164. For example, the capping layer 166 may include at least one of silicon nitride (SiN), silicon oxynitride (SiON), silicon (Si) carbon nitride (SiCN), silicon carbon nitride (SiOCN), and a combination thereof. However, example embodiments are not limited thereto.

The stacked structure SS of the semiconductor device according to some example embodiments may further include the interlayer insulating layer 195.

The interlayer insulating layer 195 may be disposed on the side surface of the spacer 164, the side surface of the capping layer 166, and the upper surface of the upper semiconductor pattern 150B. The interlayer insulating layer 195 may not cover the upper surface of the capping layer 166. The interlayer insulating layer 195 may include, for example, at least one of silicon oxide (SiO₂), silicon nitride (SiN), silicon oxynitride (SiON), and a low-k material. The low-k material may include, for example, fluorinated tetraethylorthosilicate (FTEOS), hydrogen silsesquioxane (HSQ), bis-benzocyclobutene (BCB), tetramethylorthosilicate (TMOS), octamethylcyclotetrasiloxane (OMCTS), hexamethyldisiloxane (HMDS), trimethylsilyl borate (TMSB), diacetoxyditertiarybutoxysiloxane (DADBS), trimethylsilyl phosphate (TMSP), polytetrafluoroethylene (PTFE), tonen silazen (TOSZ), fluoride silicate glass (FSG), polyimide nanofoams (PIN) such as polypropylene oxide (PPO), carbon doped silicon oxide (CDO), organo silicate glass (OSG), SiLK, amorphous fluorinated carbon (AFC), silica aerogels (SA), silica xerogels (SX), mesoporous silica (MS), or a combination thereof, but example embodiments are not limited thereto.

The stacked structure SS of the semiconductor device according to some example embodiments may further include a second liner 173.

The second liner 173 may be disposed between the spacer 164 and the interlayer insulating layer 195 and between the upper semiconductor pattern 150B and the interlayer insulating layer 195. The second liner 173 may include a material having an etch selectivity with respect to the interlayer insulating layer 195. The second liner 173 may include, for example, at least one of silicon nitride (SiN), silicon oxynitride (SiON), silicon carbonitride (SiOCN), silicon boron nitride (SiBN), silicon oxyboron nitride (SiOBN), silicon oxycarbide (SiOC), and a combination thereof. However, example embodiments are not limited thereto.

Hereinafter, the description describes the transistor structure TS.

The transistor structure TS of the semiconductor device according to some example embodiments may include the protruding pattern 110 disposed on the base insulating layer 100, the plurality of channel patterns 240 disposed on the protruding pattern 110, the intermediate insulating structure 220 disposed between the plurality of lower channel patterns 240A and the plurality of upper channel patterns 240B, the gate structure 260 disposed on the protruding pattern 110, and source/drain patterns 250 disposed on at least one side of the gate structure 260.

The semiconductor device according to some example embodiments may include at least one transistor element. For example, the semiconductor device according to some example embodiments may include a first transistor structure including the plurality of lower channel patterns 240A and a second transistor structure including the plurality of upper channel patterns 240B. The first or second transistor structure according to some example embodiments may be formed as a gate all around field effect transistor (GAAFET) structure such as a multi bridge channel field effect transistor (MBCFET™) in which the plurality of lower channel patterns 240A or the plurality of upper channel patterns 240B are surrounded by the gate structure 260.

In addition, the first or second transistor structure according to some example embodiments may be a three dimensional-stacked FET (3D-SFET) structure stacked in the third direction (Z direction). Here, the first transistor structure may be a first-type conductivity metal-oxide-semiconductor field-effect transistor (MOSFET), and the second transistor structure may be a second-type conductivity MOSFET. Here, the first-type conductivity may be the P-type conductivity, and the second-type conductivity may be the N-type conductivity. However, and example embodiments are not limited thereto. The first transistor structure may be the second-type conductivity MOSFET, and the second transistor structure may be the first-type conductivity MOSFET. Hereinafter, the description describes a case where the plurality of lower channel patterns 240A and the plurality of upper channel patterns 240B are stacked in the third direction (Z direction) to form a 3D-SFET structure. However, example embodiments are not limited thereto.

The plurality of channel patterns 240 may be disposed on the protruding pattern 110. In some example embodiments, the plurality of channel patterns 240 may include the plurality of lower channel patterns 240A disposed on the protruding pattern 110 and the plurality of upper channel patterns 240B disposed on the plurality of lower channel patterns 240A.

The plurality of lower channel patterns 240A may be disposed on the upper surface of the protruding pattern 110. The plurality of lower channel patterns 240A may be spaced apart from the protruding pattern 110 in the third direction (Z direction). The plurality of lower channel patterns 240A may be spaced apart from each other in the third direction (Z direction). In some example embodiments, the plurality of lower channel patterns 240A may be multi-channel active patterns.

In some example embodiments, the plurality of lower channel patterns 240A may have a similar shape, structure, and arrangement relationship to those of the plurality of first lower semiconductor layers 145A of the stacked structure SS. For example, the number of the plurality of lower channel patterns 240A stacked in the third direction (Z direction) may be the same as the number of the plurality of first lower semiconductor layers 145A stacked in the third direction (Z direction). In addition, each thickness of the plurality of lower channel patterns 240A in the third direction (Z direction) may be the same as each thickness of the plurality of first lower semiconductor layers 145A in the third direction (Z direction).

In some example embodiments, the plurality of lower channel patterns 240A may each include the same semiconductor material as the plurality of first lower semiconductor layers 145A. For example, the plurality of lower channel patterns 240A may include the elemental semiconductor material silicon (Si) or germanium (Ge). However, example embodiments are not limited thereto. As an example, the plurality of lower channel patterns 240A and the plurality of first lower semiconductor layers 145A may include silicon (Si). The plurality of lower channel patterns 240A may be formed by etching a portion of the substrate 101 (in FIG. 14), or may include the epitaxial layer grown from the substrate 101 (in FIG. 14).

In some example embodiments, the plurality of lower channel patterns 240A may be doped with the impurities at a lower concentration than the plurality of first lower semiconductor layers 145A, or may be undoped.

The plurality of upper channel patterns 240B may be disposed above the plurality of lower channel patterns 240A. In detail, the plurality of upper channel patterns 240B may be disposed on the upper surface of the intermediate insulating structure 220 disposed on the plurality of lower channel patterns 240A. The plurality of upper channel patterns 240B may be spaced apart from the plurality of lower channel patterns 240A in the third direction (Z direction). For example, the intermediate insulating structure 220 may be disposed between the plurality of upper channel patterns 240B and the plurality of lower channel patterns 240A, and the plurality of upper channel patterns 240B may be spaced apart from the plurality of lower channel patterns 240A in the third direction (Z direction) due to the intermediate insulating structure 220. The plurality of upper channel patterns 240B may be spaced apart from each other in the third direction (Z direction). In some example embodiments, the plurality of upper channel patterns 240B may be the multi-channel active patterns.

In some example embodiments, the plurality of upper channel patterns 240B may have a similar shape, structure, and arrangement relationship to those of the plurality of first upper semiconductor layers 145B of the stacked structure SS. For example, the number of the plurality of upper channel patterns 240B stacked in the third direction (Z direction) may be the same as the number of the plurality of first upper semiconductor layers 145B stacked in the third direction (Z direction). In addition, each thickness of the plurality of upper channel patterns 240B in the third direction (Z direction) may be the same as each thickness of the plurality of first upper semiconductor layers 145B in the third direction (Z direction).

In some example embodiments, the plurality of upper channel patterns 240B may include the same semiconductor material as the plurality of first upper semiconductor layers 145B. For example, the plurality of upper channel patterns 240B may include silicon (Si) or germanium (Ge), which is the elemental semiconductor material. However, example embodiments are not limited thereto. As an example, the plurality of upper channel patterns 240B and the plurality of first upper semiconductor layers 145B may include silicon (Si). In addition, the plurality of upper channel patterns 240B may include the same material as the plurality of lower channel patterns 240A, but example embodiments are not limited thereto. The plurality of upper channel patterns 240B may be formed by etching a portion of the substrate 101 (in FIG. 14), or may include the epitaxial layer grown from the substrate 101 (in FIG. 14).

In some example embodiments, the plurality of upper channel patterns 240B may be doped with the impurities at a lower concentration than the plurality of first upper semiconductor layers 145B, or may be undoped.

FIG. 2 shows that two lower channel patterns 240A and three upper channel patterns 240B are stacked to be spaced apart from each other in the third direction (Z direction), which is only for the convenience of description, but example embodiments are not limited thereto. For example, the plurality of lower channel patterns 240A including three or more patterns and/or the plurality of upper channel patterns 240B including three or more patterns may be stacked to be spaced apart from each other in the third direction (Z direction). Alternatively, one lower channel pattern 240A and/or one upper channel pattern 240B may be stacked to be spaced apart from each other in the third direction (Z direction).

The intermediate insulating structure 220 may be disposed on the plurality of lower channel patterns 240A. The intermediate insulating structure 220 may be disposed between the uppermost lower channel pattern 240A and the lowermost upper channel pattern 240B. In addition, the intermediate insulating structure 220 may be disposed between the uppermost lower gate structure 260A and the lowermost upper gate structure 260B.

The intermediate insulating structure 220 may include the various insulating materials. For example, the intermediate insulating structure 220 may include silicon oxide, silicon nitride, silicon oxynitride, or the combination thereof. However, example embodiments are not limited thereto. The intermediate insulating structure 220 may allow the plurality of lower channel patterns 240A and the plurality of upper channel patterns 240B to be spaced apart from each other.

FIG. 2 shows that the intermediate insulating structure 220 is formed of a single layer. However, the intermediate insulating structure 220 is not limited thereto, and may be formed of multiple layers.

The gate structure 260 may be disposed on the protruding pattern 110. The gate structure 260 may extend in the second direction (Y direction). The gate structure 260 may be spaced apart from the dummy main gate structure 160M in the first direction (X direction). The gate structure 260 may be disposed on the protruding pattern 110. The gate structure 260 may intersect the protruding pattern 110. The gate structure 260 may surround each of the plurality of channel patterns 240.

In some example embodiments, the first and second transistor structures may share one gate structure 260. For example, as shown in FIG. 4, the gate structure 260 may surround the plurality of lower channel patterns 240A and the plurality of upper channel patterns 240B, and the first and second transistor structures may thus share one gate structure 260.

The gate structure 260 may include the lower gate structure 260A, the upper gate structure 260B, and a main gate structure 260M.

The lower gate structure 260A may be disposed between the plurality of lower channel patterns 240A adjacent to each other in the third direction (Z direction), and between the protruding pattern 110 and the lowermost lower channel pattern 240A. The upper gate structure 260B may be disposed between the plurality of upper channel patterns 240B adjacent to each other in the third direction (Z direction). The uppermost main gate structure 260M may be disposed on the upper channel pattern 240B.

The lower gate structure 260A may be adjacent to a lower source/drain pattern 250A to be described below. The upper gate structure 260B may be adjacent to an upper source/drain pattern 250B to be described below. The main gate structure 260M may be disposed above/on the lower gate structure 260A, the upper gate structure 260B, and the plurality of upper channel patterns 240B.

According to some example embodiments, the lower gate structure 260A and the upper gate structure 260B may each include a plurality of layers, and the plurality of layers and the plurality of channel patterns 240 may be alternately stacked.

The lower gate structure 260A and the upper gate structure 260B may each include gate electrodes 265A and 265B and gate insulating films 262A and 262B.

The gate electrodes 265A and 265B may be disposed on/above the protruding pattern 110. For example, the lower gate electrode 265A may be disposed on the protruding pattern 110, and the upper gate electrode 265B may be disposed on the lower gate electrode 265A. The lower gate electrode 265A may surround the plurality of lower channel patterns 240A, and the upper gate electrode 265B may surround the plurality of upper channel patterns 240B.

The gate electrodes 265A and 265B may each include the conductive material. The gate electrodes 265A and 265B may each include at least one of the metal, the metal alloy, the conductive metal nitride, the metal silicide, the doped semiconductor material, the conductive metal oxide, and the conductive metal oxynitride. The gate electrodes 265A and 265B may each include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel Platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but example embodiments are not limited thereto. The conductive metal oxide and the conductive metal oxynitride may each include an oxidized form of the above-described material, but example embodiments are not limited thereto. The gate electrodes 265A and 265B may include the same material, and are not limited thereto, and the gate electrodes 265A and 265B may include different materials.

The gate insulating films 262A and 262B may each be disposed along a perimeter of the plurality of channel patterns 240. For example, the lower gate insulating film 262A may be disposed along the perimeter of the plurality of lower channel patterns 240A, and the upper gate insulating film 262B may be disposed along the perimeter of the plurality of upper channel patterns 240B. In addition, the lower gate insulating film 262A may extend along the upper surface of the protruding pattern 110. The gate insulating films 262A and 262B may each include various insulating materials.

In some example embodiments, the gate insulating film 262A or 262B is shown as a single film, but example embodiments are not limited thereto. For example, the gate insulating film 262A or 262B may be formed of a multilayer film including silicon oxide (SiO₂) and the high-k material. Here, the high-k material may include the material having a higher dielectric constant than silicon oxide (SiO₂), such as hafnium oxide (HfO), aluminum oxide (AlO), or tantalum oxide (TaO). However, example embodiments are not limited thereto.

The main gate structure 260M may be disposed above/on the upper gate structure 260B and the plurality of upper channel patterns 240B. The main gate structure 260M may be disposed on the upper surface of the plurality of upper channel patterns 240B.

In some example embodiments, the main gate structure 260M may be disposed on the same layer as the dummy main gate structure 160M of the stacked structure SS. That is, a lower surface of the main gate structure 260M may be disposed at substantially the same level as a lower surface of the dummy main gate structure 160M. In addition, a thickness of the main gate structure 260M in the third direction (Z direction) may be substantially the same as a thickness of the dummy main gate structure 160M in the third direction (Z direction). This same thickness may result from a process feature in which the main gate structure 260M and the dummy main gate structure 160M are simultaneously formed in the same process.

The main gate structure 260M may include a main gate electrode 265M and a main gate insulating film 262M.

The main gate electrode 265M may be disposed above the upper gate structure 260B and the plurality of upper channel patterns 240B. The main gate electrode 265M may be disposed above the upper surface of the plurality of upper channel patterns 240B. Accordingly, four sides of the plurality of channel patterns 240 may be surrounded by the gate electrodes 265A and 265B and the main gate electrode 265M. The main gate electrode 265M may include the same conductive material as the gate electrode 265A or 265B.

The main gate insulating film 262M may extend along the side surface of the main gate electrode 265M. The main gate insulating film 262M may extend along the side surface of the spacer 164. The main gate insulating film 262M may include the various insulating materials.

In some example embodiments, the main gate insulating film 262M is shown as a single film, but example embodiments are not limited thereto. For example, the main gate insulating film 262M may be formed of a multilayer film including silicon oxide (SiO₂) and the high-k material. Here, the high-k material may include the material having a higher dielectric constant than silicon oxide (SiO₂), such as hafnium oxide (HfO), aluminum oxide (AlO), or tantalum oxide (TaO). However, example embodiments are not limited thereto.

In some example embodiments, the spacer 164 may further be disposed on the side surface of the main gate electrode 265M. The spacer 164 may not be disposed between the protruding pattern 110 and the plurality of channel patterns 240. The spacer 164 may not be disposed between the plurality of channel patterns 240 adjacent to each other in the third direction (Z direction).

In some example embodiments, the capping layer 166 may further be disposed on the main gate structure 260M and the spacer 164. The upper surface of the capping layer 166 may be coplanar (and/or substantially coplanar) with the upper surface of the interlayer insulating layer 195.

The source/drain pattern 250 may be disposed on at least one side of the gate structure 260. For example, the source/drain pattern 250 may be disposed on each of two sides of the gate structure 260. The source/drain pattern 250 may be disposed on the protruding pattern 110. The source/drain pattern 250 may be in contact with the side surface of the plurality of channel patterns 240. The source/drain pattern 250 may be connected to the plurality of channel patterns 240.

The source/drain pattern 250 according to some example embodiments may include the lower source/drain pattern 250A and the upper source/drain pattern 250B.

The lower source/drain pattern 250A may be disposed on the protruding pattern 110. The lower source/drain pattern 250A may be disposed on at least one side of the lower gate structure 260A. For example, the lower source/drain pattern 250A may be disposed on each of two sides of the lower gate structure 260A. The lower source/drain pattern 250A may be connected to the plurality of lower channel patterns 240A.

In some example embodiments, the lower source/drain pattern 250A may have substantially the same shape as the lower semiconductor pattern 150A of the stacked structure SS. For example, the lower source/drain pattern 250A may be disposed in a trench extending in the third direction (Z direction). At least a portion of the lower source/drain pattern 250A may be surrounded by the protruding pattern 110. A lower surface of the lower source/drain pattern 250A may be closer to the upper surface of the base insulating layer 100 than to a lower surface of the lower channel pattern 240A. This arrangement may result from a process feature in which the lower source/drain pattern 250A and the lower semiconductor pattern 150A are simultaneously formed.

The lower source/drain pattern 250A may be the epitaxial pattern formed by the selective epitaxial growth process of using the active pattern 111 (in FIG. 14) and the plurality of lower channel patterns 240A as its seeds. The lower source/drain pattern 250A may serve as a source/drain of the transistor using the plurality of lower channel patterns 240A as the channel region.

The lower source/drain pattern 250A may have the first-type conductivity. The lower semiconductor pattern 150A may be doped with the first-type conductivity impurities. Here, the first-type conductivity may be the P-type conductivity, but example embodiments are not limited thereto. For example, the lower source/drain pattern 250A may include boron (B), vanadium (V), indium (In), gallium (Ga), aluminum (Al), or the combination thereof. However, example embodiments are not limited thereto.

The lower source/drain pattern 250A of the semiconductor device according to some example embodiments may include a first lower source/drain layer 251A and a second lower source/drain layer 252A.

The first lower source/drain layer 251A may be disposed on a side surface of the plurality of lower channel patterns 240A and the upper surface of the protruding pattern 110. The first lower source/drain layer 251A may include the semiconductor material. The first lower source/drain layer 251A may include the same material as the first sub-lower pattern 151A. For example, the first lower source/drain layer 251A may include silicon (Si) or silicon germanium (SiGe), which is the semiconductor material. However, example embodiments are not limited thereto.

The second lower source/drain layer 252A may be disposed on the first lower source/drain layer 251A. The second lower source/drain layer 252A may be surrounded by the first lower source/drain layer 251A. An upper surface of the second lower source/drain layer 252A may be disposed at the same level as an upper surface of the first lower source/drain layer 251A.

The second lower source/drain layer 252A may include the semiconductor material. The second lower source/drain layer 252A may include the same semiconductor material as the second sub-lower pattern 152A. As an example, the second lower source/drain layer 252A may include silicon (Si) or silicon germanium (SiGe), which is the semiconductor material. However, example embodiments are not limited thereto.

In some example embodiments, the first lower source/drain layer 251A and the second lower source/drain layer 252A may each have the first-type conductivity. The first lower source/drain layer 251A and the second lower source/drain layer 252A may each be doped with the first-type conductivity impurities. Here, the first-type conductivity may be the P-type conductivity. Here, the impurities in the first lower source/drain layer 251A may have a doping concentration less than or substantially equal to the doping concentration of the impurities in the first sub-lower pattern 151A of the stacked structure SS. In addition, the impurities in the second lower source/drain layer 252A may have a doping concentration less than or substantially equal to the doping concentration of the impurities in the second sub-lower pattern 152A of the stacked structure SS. However, example embodiments are not limited thereto, and the impurities in the first lower source/drain layer 251A may have the doping concentration greater than the doping concentration of the impurities in the first sub-lower pattern 151A of the stacked structure SS. The impurities in the second lower source/drain layer 252A may have a doping concentration greater than the doping concentration of the impurities in the second sub-lower pattern 152A of the stacked structure SS. As another example, the first lower source/drain layer 251A and the second lower source/drain layer 252A may each have the second-type conductivity.

In some example embodiments, the lower source/drain pattern 250A is described as being formed of the multiple layers, is not limited thereto, and may be formed of a single layer that includes the semiconductor material.

The upper source/drain pattern 250B of the semiconductor device according to some example embodiments may be disposed above the lower source/drain pattern 250A.

The upper source/drain pattern 250B may be spaced apart from the lower source/drain pattern 250A in the third direction (Z direction). For example, the barrier structure 170 may be disposed between the upper source/drain pattern 250B and the lower source/drain pattern 250A, and the upper source/drain pattern 250B and the lower source/drain pattern 250A may be spaced apart from each other due to the barrier structure 170. Accordingly, the upper source/drain pattern 250B and the lower source/drain pattern 250A may be electrically insulated from each other.

The upper source/drain pattern 250B may be disposed on at least one side of the upper gate structure 260B. For example, the upper source/drain pattern 250B may be disposed on each of two sides of the upper gate structure 260B. The upper source/drain pattern 250B may be connected to the plurality of upper channel patterns 240B.

In some example embodiments, the upper source/drain pattern 250B may have substantially the same shape as the upper semiconductor pattern 150B of the stacked structure SS. For example, a lower surface of the upper source/drain pattern 250B may be disposed at substantially the same level as the lower surface of the upper semiconductor pattern 150B. An upper surface of the upper source/drain pattern 250B may be disposed at substantially the same level as the upper surface of the upper semiconductor pattern 150B. This feature may result from a process feature in which the upper source/drain pattern 250B and the upper semiconductor pattern 150B are simultaneously formed.

The upper source/drain pattern 250B may be the epitaxial pattern formed by the selective epitaxial growth process using the plurality of upper channel patterns 240B as its seeds. Here, the upper source/drain pattern 250B may be a pattern formed using only side surfaces of the plurality of upper channel patterns 240B as its seeds. That is, unlike the lower source/drain pattern 250A, which is a pattern formed using the upper surface of the active pattern 111 (in FIG. 14) and the side surface of the plurality of lower channel patterns 240A as its seeds, the upper source/drain pattern 250B may be a pattern formed using only the side surfaces of the plurality of upper channel patterns 240B as its seeds. The upper source/drain pattern 250B may serve as a source/drain of the transistor using the plurality of upper channel patterns 240B as the channel region.

The upper source/drain pattern 250B of the semiconductor device according to some example embodiments may include a first upper source/drain layer 251B and a second upper source/drain layer 252B.

The first upper source/drain layer 251B may be disposed on the side surface of the plurality of upper channel patterns 240B. The first upper source/drain layer 251B may be disposed on the barrier structure 170. The first upper source/drain layer 251B may include the semiconductor material. The first upper source/drain layer 251B may include the same material as the first sub-upper pattern 151B. For example, the first upper source/drain layer 251B may include silicon (Si) or silicon germanium (SiGe), which is the semiconductor material. However, example embodiments are not limited thereto.

In some example embodiments, the first upper source/drain layer 251B may have substantially the same shape as the first sub-upper pattern 151B. For example, a side surface of the first upper source/drain layer 251B may include a curved surface protruding convexly from the side surfaces of the plurality of upper channel patterns 240B.

The second upper source/drain layer 252B may be disposed between the first upper source/drain layers 251B. The second upper source/drain layer 252B may be disposed on the barrier structure 170.

The second upper source/drain layer 252B may include the semiconductor material. The second upper source/drain layer 252B may include the same semiconductor material as the second sub-upper pattern 152B. As an example, the second upper source/drain layer 252B may include silicon (Si) or silicon germanium (SiGe), which is the semiconductor material. However, example embodiments are not limited thereto.

In some example embodiments, the first upper source/drain layer 251B and the second upper source/drain layer 252B may each have the second-type conductivity. The first upper source/drain layer 251B and the second upper source/drain layer 252B may each be doped with the second-type conductivity impurities. Here, the second-type conductivity may be the N-type conductivity. Here, the impurities in the first upper source/drain layer 251B may have a doping concentration less than or substantially equal to the doping concentration of the impurities in the first sub-upper pattern 151B of the stacked structure SS. In addition, the impurities in the second upper source/drain layer 252B may have a doping concentration less than or substantially equal to the doping concentration of the impurities in the second sub-upper pattern 152B of the stacked structure SS. However, example embodiments are not limited thereto, and the impurities in the first upper source/drain layer 251B may have the doping concentration greater than the doping concentration of the impurities in the first sub-upper pattern 151B of the stacked structure SS. The impurities in the second upper source/drain layer 252B may have the doping concentration greater than the doping concentration of the impurities in the second sub-upper pattern 152B of the stacked structure SS. As another example, the first upper source/drain layer 251B and the second upper source/drain layer 252B may each have the first-type conductivity.

In some example embodiments, the barrier structure 170 may be further disposed between the lower source/drain pattern 250A and the upper source/drain pattern 250B. The barrier structure 170 may overlap the lower source/drain pattern 250A and the upper source/drain pattern 250B in the third direction (Z direction). The barrier structure 170 may be disposed on the side surface of the intermediate insulating structure 220. The upper surface and lower surface of the barrier structure 170 may be flat, but example embodiments are not limited thereto. For example, the upper surface and/or lower surface of the barrier structure 170 may be upwardly convex or downwardly convex.

The semiconductor device according to some example embodiments may further include an upper contact structure 180 and a lower contact structure 190.

The upper contact structure 180 may be disposed on the upper semiconductor pattern 150B or the upper source/drain pattern 250B. For example, a first upper contact structure 180_1 may be electrically connected to the upper semiconductor pattern 150B by passing through the interlayer insulating layer 195. A second upper contact structure 180_2 may be electrically connected to the upper source/drain pattern 250B by passing through the interlayer insulating layer 195. The upper contact structure 180 may have an inclined side surface whose lower width is narrower than its upper width based on its aspect ratio, but example embodiments are not limited thereto. The upper contact structure 180 may recess the upper semiconductor pattern 150B and the upper source/drain pattern 250B to a desired (and/or alternatively predetermined) depth.

The upper contact structure 180 of the semiconductor device according to some example embodiments may include an upper contact electrode 186, and an upper silicide film 182 disposed between the upper contact electrode 186 and the upper semiconductor pattern 150B.

The upper contact electrode 186 may include, for example, at least one of the metal, the metal alloy, the conductive metal nitride, the conductive metal carbide, the conductive metal oxide, the conductive metal carbonitride, and a two-dimensional (2D) material. However, example embodiments are not limited thereto. The upper silicide film 182 may surround a portion of the upper contact electrode 186 that is indented into the upper semiconductor pattern 150B. The upper silicide film 182 may include metal-silicide. For example, the upper silicide film 182 may include at least one of titanium-silicide, tantalum-silicide, tungsten-silicide, nickel-silicide, and cobalt-silicide. However, example embodiments are not limited thereto. In some example embodiments, the number and arrangement shape of the conductive layers included in the upper contact structure 180 may be varied.

The lower contact structure 190 may be disposed on the lower semiconductor pattern 150A or the lower source/drain pattern 250A. For example, a first lower contact structure 190-1 may be electrically connected to the lower semiconductor pattern 150A by passing through the base insulating layer 100. A second lower contact structure 190_2 may be electrically connected to the lower source/drain pattern 250A by passing through the base insulating layer 100. The lower contact structure 190 may recess the lower semiconductor pattern 150A and the lower source/drain pattern 250A to a desired (and/or alternatively predetermined) depth. The lower contact structure 190 of the semiconductor device according to some example embodiments may include a lower contact electrode 196, a lower silicide film 192 disposed between the lower contact electrode 196 and the lower semiconductor pattern 150A. Descriptions of the lower contact electrode 196 and the lower silicide film 192 are substantially the same as the descriptions of the upper contact electrode 186 and the upper silicide film 182, and the description thus omits their descriptions.

In the semiconductor device according to some example embodiments, the transistor structure TS and the stacked structure SS including the diode element or the like may be simultaneously formed on the base insulating layer 100 and/or the semiconductor substrate. Accordingly, the stacked structure SS including the diode element or the like may be formed together with the transistor structure TS without significantly increasing the number of manufacturing processes, thereby increasing the integration of the semiconductor device and/or reducing manufacturing costs.

Hereinafter, the stacked structure of the semiconductor device according to some example embodiments is described with reference to FIGS. 6 to 10.

FIGS. 6 to 10 are cross-sectional views corresponding to region S1 in FIG. 2 and showing the semiconductor device according to some example embodiments.

The embodiments shown in FIGS. 6 to 10 are substantially the same as the embodiments shown in FIGS. 1 to 5, and therefore, their descriptions are omitted and their differences are mainly described.

Referring to FIGS. 6 and 7, the PN junction interface 300_J between the first doped layer 320 and second doped layer 310 of the semiconductor device according to some example embodiments may have various shapes.

For example, as shown in FIG. 6, the PN junction interface 300_J between the first doped layer 320 and the second doped layer 310 may be concave toward the upper surface of the lower sheet structure 140A. That is, the upper surface of the first doped layer 320 may be concave toward the upper surface of the lower sheet structure 140A, and the lower surface of the second doped layer 310 may be convex toward the upper surface of the lower sheet structure 140A. The upper surface of the first doped layer 320 may be disposed at a lower level than the upper surface of the barrier structure 170. That is, the upper surface of the first doped layer 320 may be at a level closer to a level of the upper surface of the lower sheet structure 140A in a third direction (Z direction) than to a level of the upper surface of the barrier structure 170 in a third direction (Z direction). Here, the upper surface of the first doped layer 320 may have the complementary shape to the lower surface of the second doped layer 310.

As another example, as shown in FIG. 7, the PN junction interface 300_J between the first doped layer 320 and the second doped layer 310 may be convex toward the upper surface of the upper sheet structure 140B. That is, the upper surface of the first doped layer 320 may be convex toward the upper surface of the upper sheet structure 140B, and the lower surface of the second doped layer 310 may be concave toward the upper surface of the upper sheet structure 140B. The upper surface of the first doped layer 320 may be disposed at a higher level than the upper surface of the barrier structure 170. That is, a level of the upper surface of the first doped layer 320 in a third direction (Z direction) may be farther from a level of the upper surface of the lower sheet structure 140A than from a level of the upper surface of the barrier structure 170 in a third direction (Z direction). However, example embodiments are not limited thereto, and the upper surface of the first doped layer 320 may be disposed at a level lower than or substantially the same as a level of the upper surface of the barrier structure 170. In some example embodiments, the first doped layer 320 may have at least a portion overlapping the upper semiconductor pattern 150B in the first direction (X direction), but example embodiments are not limited thereto.

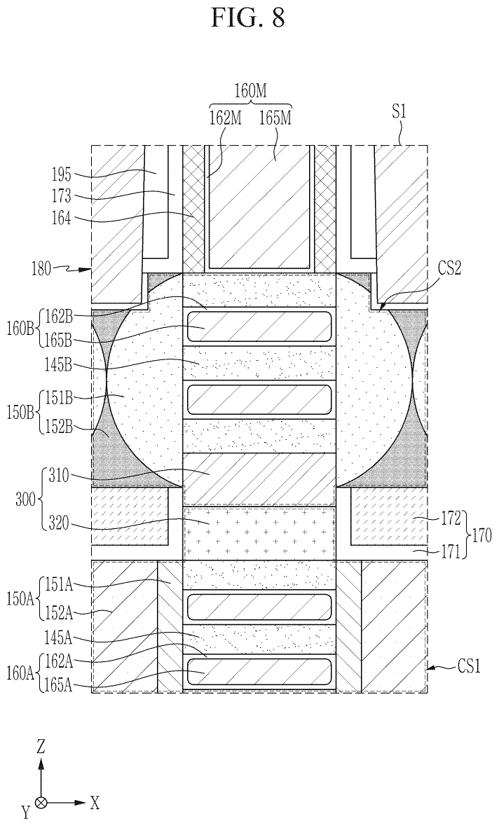

Referring to FIG. 8, the stacked structure SS of the semiconductor device according to some example embodiments may include a dummy lower gate structure 160A and a dummy upper gate structure 160B. In some example embodiments as seen in FIG. 8, the lower sheet structure 140A does not include the plurality of second lower semiconductor layers 142A, and the upper sheet structure 140B does not include the plurality of second upper semiconductor layers 142B, unlike the embodiments in FIGS. 1 to 5.

In some example embodiments, the dummy lower gate structures 160A may be stacked to be spaced apart from each other in the third direction (Z direction). The plurality of first lower semiconductor layers 145A may be disposed between the dummy lower gate structures 160A stacked to be spaced apart from each other in the third direction (Z direction). That is, the plurality of first lower semiconductor layers 145A and the dummy lower gate structure 160A may be alternately stacked in the third direction (Z direction). In some example embodiments, the dummy lower gate structure 160A may float. For example, the dummy lower gate structure 160A may not be electrically connected to the gate structure 260 of the transistor structure TS. In some example embodiments, the dummy lower gate structure 160A may have a similar shape, structure, and arrangement relationship to those of the lower gate structure 260A included in the transistor structure TS.

The dummy upper gate structures 160B may be stacked to be spaced apart from each other in the third direction (Z direction). The plurality of first upper semiconductor layers 145B may be disposed between the dummy upper gate structures 160B stacked to be spaced apart from each other in the third direction (Z direction). That is, the plurality of first upper semiconductor layers 145B and the dummy upper gate structure 160B may be alternately stacked in the third direction (Z direction). In some example embodiments, the dummy upper gate structure 160B may float. For example, the dummy upper gate structure 160B may not be electrically connected to the gate structure 260 of the transistor structure TS. In some example embodiments, the dummy upper gate structure 160B may have a similar shape, structure, and arrangement relationship to those of the upper gate structure 260B included in the transistor structure TS.

The dummy lower gate structure 160A and the dummy upper gate structure 160B may each include dummy gate electrodes 165A and 165B and dummy gate insulating films 162A and 162B. Descriptions of the dummy gate electrodes 165A and 165B and the dummy gate insulating films 162A and 162B are substantially the same as the descriptions of the gate electrodes 265A and 265B and the gate insulating films 262A and 262B included in the transistor structure TS, and the description thus omits their descriptions.

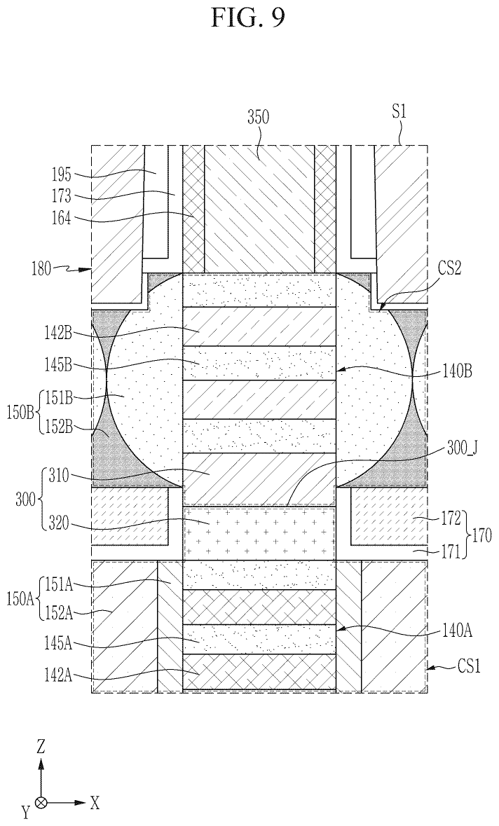

Referring to FIG. 9, the stacked structure SS of the semiconductor device according to some example embodiments may include a dummy gate pattern 350 disposed on the upper sheet structure 140B, and may not include the dummy main gate structure 160M.

In some example embodiments, the dummy gate pattern 350 may extend in the second direction (Y direction). The dummy gate pattern 350 may intersect the protruding pattern 110. The dummy gate pattern 350 may be disposed on the uppermost first upper semiconductor layer 145B. The dummy gate pattern 350 may be disposed on the side surface of the upper sheet structure 140B in the second direction (Y direction) and the side surface of the lower sheet structure 140A in the second direction (Y direction). The dummy gate pattern 350 may be disposed on the side surface of the PN junction structure 300 in the second direction (Y direction). In some example embodiments, the dummy gate pattern 350 may float.

In some example embodiments, the dummy gate pattern 350 may include, for example, polysilicon, but example embodiments are not limited thereto. The dummy gate pattern 350 may include a same material as a sacrificial gate structure 400 (in FIG. 14). The dummy gate pattern 350 may be formed as at least a portion of the sacrificial gate structure 400 (in FIG. 14).

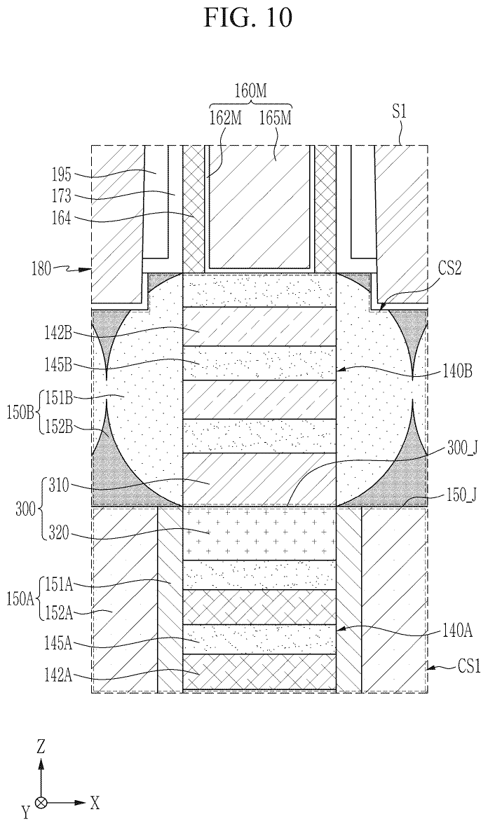

Referring to FIG. 10, the stacked structure SS of the semiconductor device according to some example embodiments may not include the barrier structure 170.

In some example embodiments, the lower semiconductor pattern 150A may be in contact with the upper semiconductor pattern 150B. The lower semiconductor pattern 150A may form an interface 150_J with the upper semiconductor pattern 150B, and the interface 150_J between the lower semiconductor pattern 150A and the upper semiconductor pattern 150B may form the PN junction interface.

The upper surface of the lower semiconductor pattern 150A may be farther from the upper surface of the base insulating layer 100 than from the upper surface of the lower sheet structure 140A. Accordingly, a side surface of the lower semiconductor pattern 150A may be in contact with the first doped layer 320. The lower semiconductor pattern 150A may overlap the first doped layer 320 in the first direction (X direction). In some example embodiments, the upper surface of the lower semiconductor pattern 150A may be disposed at substantially the same distance from the upper surface of the first doped layer 320 and the upper surface of the lower sheet structure 140A.

In addition, the lower surface of the upper semiconductor pattern 150B may be closer to the upper surface of the lower sheet structure 140A than to the lower surface of the upper sheet structure 140B. The lower surface of the upper semiconductor pattern 150B may be disposed at substantially the same distance from the lower surface of the second doped layer 310 and the upper surface of the lower sheet structure 140A.

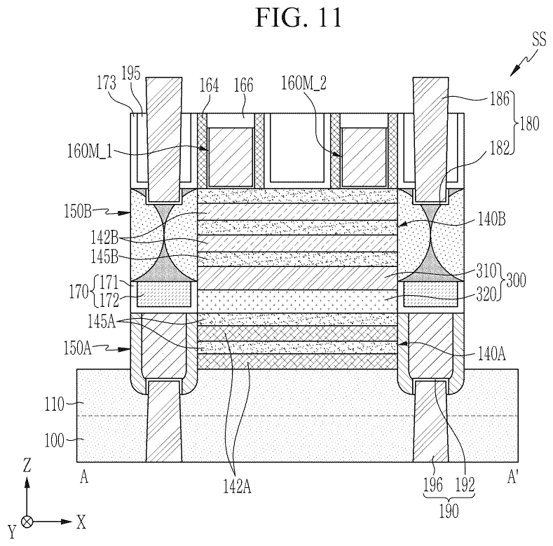

Hereinafter, the semiconductor device according to some example embodiments are described with reference to FIGS. 11 to 13.

FIGS. 11 to 13 are cross-sectional views corresponding to a region taken along line A-A′ in FIG. 1 and showing the semiconductor device according to some example embodiments. FIGS. 11 to 13 show stacked structures SS1 and SS2 for the convenience of description, and omit showing the transistor structure TS (in FIG. 2). The transistor structure TS (in FIG. 2) may be disposed on one side of the stacked structures SS1 and SS2 of FIGS. 11 to 13.

The embodiments shown in FIGS. 11 to 13 are substantially the same as the embodiments shown in FIGS. 1 to 5, and therefore, their descriptions are omitted and their differences are mainly described.

Referring to FIG. 11, the stacked structure SS of the semiconductor device according to some example embodiments may include the plurality of dummy main gate structures 160M disposed on the upper sheet structure 140B.

In some example embodiments, the plurality of dummy main gate structures 160M may be disposed between the adjacent upper semiconductor patterns 150B and spaced apart from each other in the first direction (X direction). For example, a first dummy main gate structure 160M_1 and a second dummy main gate structure 160M_2 may be disposed between the adjacent upper semiconductor patterns 150B and spaced apart from each other in the first direction (X direction). The interlayer insulating layer 195 and the second liner 173 may be disposed between the first dummy main gate structure 160M_1 and the second dummy main gate structure 160M_2. The first dummy main gate structure 160M_1 and the second dummy main gate structure 160M_2 may be spaced apart from each other due to the interlayer insulating layer 195 and the second liner 173.

FIG. 11 shows that two dummy main gate structures 160M_1 and 160M_2 are disposed between the adjacent upper semiconductor patterns 150B in the first direction (X direction), and the number of the dummy main gate structures 160M is not limited thereto.

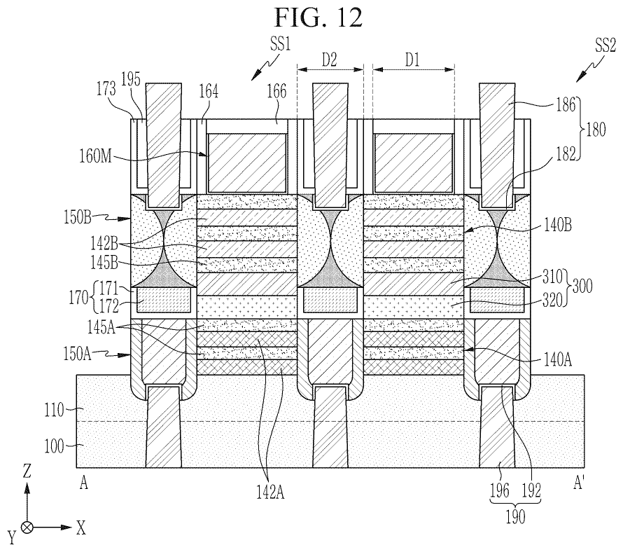

Referring to FIG. 12, the dummy main gate structure 160M of the semiconductor device according to some example embodiments may have a first width D1 greater than or substantially equal to a second width D2 of the upper semiconductor pattern 150B in the first direction (X direction). Accordingly, the upper sheet structure 140B in the first direction (X direction) may have a width greater than or substantially equal to the second width D2 of the upper semiconductor pattern 150B in the first direction (X direction). In addition, the lower sheet structure 140A in the first direction (X direction) may have a width greater than or substantially equal to the second width D2 of the lower semiconductor pattern 150A in the first direction (X direction).

The semiconductor device according to some example embodiments may include the first stacked structure SS1 and the second stacked structure SS2 adjacent to each other in the first direction (X direction). In some example embodiments, the first stacked structure SS1 and the second stacked structure SS2 may share one upper semiconductor pattern 150B and one lower semiconductor pattern 150A, but example embodiments are not limited thereto.

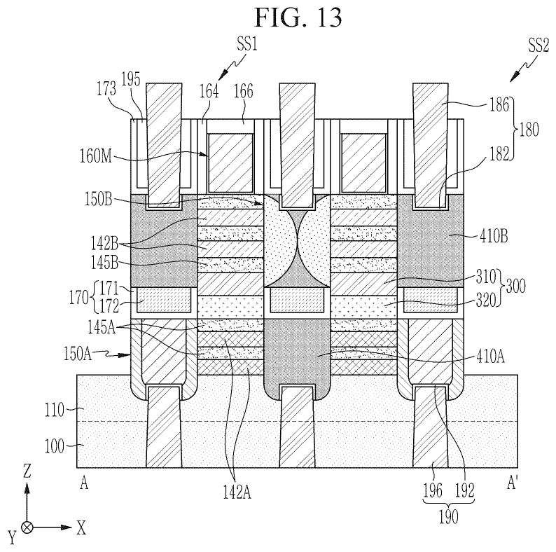

Referring to FIG. 13, the semiconductor device according to some example embodiments may include the first stacked structure SS1 and the second stacked structure SS2 adjacent to each other in the first direction (X direction). The first stacked structure SS1 and the second stacked structure SS2 may share one upper semiconductor pattern 150B.

In some example embodiments, the stacked structures SS1 and SS2 may form a bipolar junction transistor (BJT). For example, the stacked structures SS1 and SS2 may form a PNP junction transistor, and may also form an NPN junction transistor.

In some example embodiments, the stacked structures SS1 and SS2 may include a lower dummy pattern 410A and an upper dummy pattern 410B. For example, as shown in FIG. 13, the stacked structures SS1 and SS2 may include one lower dummy pattern 410A and two upper dummy patterns 410B. The lower dummy pattern 410A may be disposed between the adjacent lower sheet structures 140A in the first direction (X direction), and the upper dummy pattern 410B may be disposed between the adjacent upper sheet structures 140B in the first direction (X direction).

The lower dummy pattern 410A and the upper dummy pattern 410B may each include the semiconductor material. In some example embodiments, the lower dummy pattern 410A may be doped with substantially no impurities, or doped with the impurities having a lower concentration than those in the lower semiconductor pattern 150A. The upper dummy pattern 410B may be doped with substantially no impurities, or doped with the impurities having a lower concentration than those in the upper semiconductor pattern 150B. The lower dummy pattern 410A may not be electrically connected to the lower sheet structure 140A. The lower dummy pattern 410A may float. The upper dummy pattern 410B may not be electrically connected to the upper sheet structure 140B. The upper dummy pattern 410B may float.

Accordingly, a PN junction interface may be formed between the lower semiconductor pattern 150A, lower sheet structure 140A, and first doped layer 320 of the first stacked structure SS1 that have the first-type conductivity and the upper semiconductor pattern 150B, upper sheet structure 140B, and second doped layer 310 of the first stacked structure SS1 that have the second-type conductivity, and between the upper semiconductor pattern 150B, upper sheet structure 140B, and second doped layer 310 of the second stacked structure SS2 that have the second-type conductivity and the lower semiconductor pattern 150A, lower sheet structure 140A, and first doped layer 320 of the second stacked structure SS2 that have the first-type conductivity. Therefore, the first stacked structure SS1 and the second stacked structure SS2 may form the PNP junction transistor.

However, example embodiments are not limited thereto, the first stacked structure SS1 and the second stacked structure SS2 may form the NPN junction transistor based on the arrangement of the lower dummy pattern 410A and the upper dummy pattern 410B.

FIG. 13 shows one lower dummy pattern 410A and two upper dummy patterns 410B, and the numbers of the lower dummy patterns 410A and the upper dummy patterns 410B are not limited thereto and may vary based on their design.

Hereinafter, a method for manufacturing a semiconductor device according to some example embodiments is described with reference to FIGS. 14 to 21.

FIGS. 14 to 21 are cross-sectional views showing intermediate stages of the method for manufacturing a semiconductor device according to some example embodiments.

As shown in FIG. 14, a preliminary lower sheet structure 140AP, the preliminary intermediate insulating structure 220P, a preliminary upper sheet structure 140BP may be formed in a first region AR1 of the substrate 101, and a sacrificial gate structure 400 may then be formed thereon. In addition, the lower sacrificial layer 220A, the upper sacrificial layer 220B, the plurality of lower channel patterns 240A, the preliminary intermediate insulating structure 220P, and the plurality of upper channel patterns 240B may be formed in a second region AR2 of the substrate 101, and the sacrificial gate structure 400 may then be formed.

The substrate 101 may be a silicon-on-insulator (SOI) or bulk silicon. Alternatively, the substrate 101 may be a silicon substrate, or may include another material, such as silicon germanium (SiGe), silicon germanium on insulator (SGOI), indium antimonide, lead telluride, indium arsenide, indium phosphide, gallium arsenide, or gallium antimonide, but example embodiments are not limited thereto.

In some example embodiments, the substrate 101 may include the first region AR1 and the second region AR2. The second region AR2 may be disposed in one side of the first region AR1 in the first direction (X direction), but example embodiments are not limited thereto. The first region AR1 may be a region where the stacked structure SS (in FIG. 2), as shown in the example embodiments relating to FIGS. 1 to 5, are formed. The second region AR2 may be a region where the transistor structure TS (in FIG. 2), as shown in the example embodiments relating to FIGS. 1 to 5, is formed.

First, the preliminary lower sheet structure 140AP, the preliminary intermediate insulating structure 220P, and the preliminary upper sheet structure 140BP may be sequentially formed in the first region AR1 of the substrate 101.

In detail, the preliminary lower sheet structure 140AP may be formed by a plurality of second preliminary lower semiconductor layers 142AP and a plurality of first preliminary lower semiconductor layers 145AP, which are alternately formed in the first region AR1 of the substrate 101. The plurality of second preliminary lower semiconductor layers 142AP may be formed of the semiconductor material having the etch selectivity with respect to the plurality of first preliminary lower semiconductor layers 145AP. As an example, the plurality of second preliminary lower semiconductor layers 142AP may include silicon germanium (SiGe), the plurality of first preliminary lower semiconductor layers 145AP may include silicon (Si), but example embodiments are not limited thereto.

The preliminary intermediate insulating structure 220P may be formed on the preliminary lower sheet structure 140AP. The preliminary intermediate insulating structure 220P may be formed of the semiconductor material having the etch selectivity with respect to the preliminary lower sheet structure 140AP. As an example, the preliminary intermediate insulating structure 220P may include silicon germanium (SiGe), but example embodiments are not limited thereto. Here, the germanium (Ge) content (at %) in the preliminary intermediate insulating structure 220P may be different from a germanium (Ge) content (at %) in the plurality of second preliminary lower semiconductor layers 142AP. In addition, the germanium (Ge) content (at %) in the preliminary intermediate insulating structure 220P may be different from the germanium (Ge) content (at %) in the lower sacrificial layer 220A and the germanium (Ge) content (at %) in the upper sacrificial layer 220B.

The preliminary upper sheet structure 140BP may be formed by alternately forming a plurality of second preliminary upper semiconductor layers 142BP and a plurality of first preliminary upper semiconductor layers 145BP on the preliminary intermediate insulating structure 220P. The plurality of second preliminary upper semiconductor layers 142BP may be formed of the semiconductor material having the etch selectivity with respect to the plurality of first preliminary upper semiconductor layers 145BP. As an example, the plurality of second preliminary upper semiconductor layers 142BP may include silicon germanium (SiGe), the plurality of first preliminary upper semiconductor layers 145BP may include silicon (Si), but example embodiments are not limited thereto.

In addition, the lower sacrificial layer 220A, the plurality of lower channel patterns 240A, the preliminary intermediate insulating structure 220P, the upper sacrificial layer 220B, and the plurality of upper channel patterns 240B may be formed in the second region AR2 of the substrate 101.

The lower sacrificial layer 220A and the plurality of lower channel patterns 240A may be alternately stacked in the third direction (Z direction). In some example embodiments, the lower sacrificial layer 220A may be formed simultaneously with the plurality of second preliminary lower semiconductor layers 142AP in the same process. Accordingly, the lower sacrificial layer 220A may be disposed on the same layer as the plurality of second preliminary lower semiconductor layers 142AP. The lower sacrificial layer 220A may include the same material as the plurality of second preliminary lower semiconductor layers 142AP. In addition, the plurality of lower channel patterns 240A may be formed simultaneously with the plurality of first preliminary lower semiconductor layers 145AP in the same process. Accordingly, the plurality of lower channel patterns 240A may be disposed on the same layer as the plurality of first preliminary lower semiconductor layers 145AP. The plurality of lower channel patterns 240A may include the same material as the plurality of first preliminary lower semiconductor layers 145AP.

The upper sacrificial layer 220B and the plurality of upper channel patterns 240B may be alternately stacked in the third direction (Z direction). In some example embodiments, the upper sacrificial layer 220B may be formed simultaneously with the plurality of second preliminary upper semiconductor layers 142BP in the same process. Accordingly, the upper sacrificial layer 220B may be disposed on the same layer as the plurality of second preliminary upper semiconductor layers 142BP. The upper sacrificial layer 220B may include the same material as the plurality of second preliminary upper semiconductor layers 142BP. In addition, the plurality of upper channel patterns 240B may be formed simultaneously with the plurality of first preliminary upper semiconductor layers 145BP in the same process. Accordingly, the plurality of upper channel patterns 240B may be disposed on the same layer as the plurality of first preliminary upper semiconductor layers 145BP. The plurality of upper channel patterns 240B may include the same material as the plurality of first preliminary upper semiconductor layers 145BP.

The preliminary lower sheet structure 140AP, the preliminary upper sheet structure 140BP, the preliminary intermediate insulating structure 220P, the lower sacrificial layer 220A, the plurality of lower channel patterns 240A, the upper sacrificial layer 220B, and the plurality of upper channel patterns 240B, which are formed in the first region AR1 of the substrate 101, may be formed by performing the epitaxial growth process using the substrate 101 as their seed.

In some example embodiments, the number of the plurality of lower channel patterns 240A that are alternately stacked with the lower sacrificial layer 220A and the number of the plurality of upper channel patterns 240B that are alternately stacked with the upper sacrificial layer 220B may vary in the embodiments.

Next, the active pattern 111 may be formed by etching the preliminary lower sheet structure 140AP, the preliminary upper sheet structure 140BP, the preliminary intermediate insulating structure 220P, the lower sacrificial layer 220A, the plurality of lower channel patterns 240A, the upper sacrificial layer 220B, the plurality of upper channel patterns 240B, and a portion of the substrate 101, and the field insulating layer 105 (in FIG. 3) may then be formed.

The active pattern 111 may be formed by removing at least a portion of the substrate 101. The active patterns 111 may extend in the first direction (X direction) and be spaced apart from each other in the second direction (Y direction).

Next, the sacrificial gate structure 400 may be formed in the first region AR1 and second region AR2 of the substrate 101. For example, the sacrificial gate structure 400 may be formed on the plurality of upper channel patterns 240B and the preliminary upper sheet structure 140BP.

The sacrificial gate structure 400 may include first and second sacrificial gate electrodes 402 and 405 and a preliminary capping layer 406 sequentially disposed on the plurality of upper channel patterns 240B and the preliminary upper sheet structure 140BP. The first sacrificial gate electrode 402 may include, for example, silicon oxide (SiO₂), but example embodiments are not limited thereto. The second sacrificial gate electrode 405 may include, for example, polysilicon, but example embodiments are not limited thereto. The preliminary capping layer 406 may include, for example, silicon nitride, but example embodiments are not limited thereto. In addition, the spacer 164 may be formed on a side surface of the sacrificial gate structure 400.

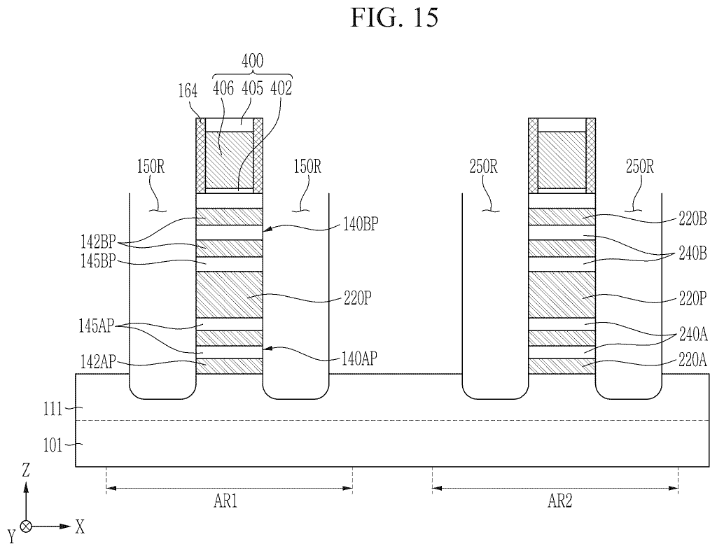

As shown in FIG. 15, a first recess 150R may be formed using the sacrificial gate structure 400 as a mask pattern in an etching process, the preliminary upper sheet structure 140BP, the preliminary intermediate insulating structure 220P, and the preliminary lower sheet structure 140AP. In addition, a second recess 250R may be formed using the sacrificial gate structure 400 as the mask to pattern the upper sacrificial layer 220B, the plurality of upper channel patterns 240B, the preliminary intermediate insulating structure 220P, the lower sacrificial layer 220A, and the plurality of lower channel patterns 240A.

The first recess 150R may be disposed in the first region AR1 of the substrate 101. The first recess 150R may pass through the preliminary upper sheet structure 140BP, the preliminary intermediate insulating structure 220P, and the preliminary lower sheet structure 140AP. In some example embodiments, the first recess 150R may have substantially the same lower and upper widths on the cross section in the first-third direction (X-Z direction), but example embodiments are not limited thereto. For example, the first recess 150R may have an inclined side surface whose lower width is narrower than its upper width based on its aspect ratio. Here, the first recess 150R may indicate a region where the upper semiconductor pattern 150B and the lower semiconductor pattern 150A are formed in a subsequent process.

The second recess 250R may be disposed in the second region AR2 of the substrate 101. The second recess 250R may pass through the upper sacrificial layer 220B, the plurality of upper channel patterns 240B, the preliminary intermediate insulating structure 220P, the lower sacrificial layer 220A, and the plurality of lower channel patterns 240A. In some example embodiments, the second recess 250R may have substantially the same lower and upper widths on the cross section in the first-third direction (X-Z direction), but example embodiments are not limited thereto. For example, the second recess 250R may have an inclined side surface whose lower width is narrower than its upper width based on its aspect ratio. Here, the second recess 250R may indicate a region where the upper source/drain pattern 250B and the lower source/drain pattern 250A are formed in the subsequent process.

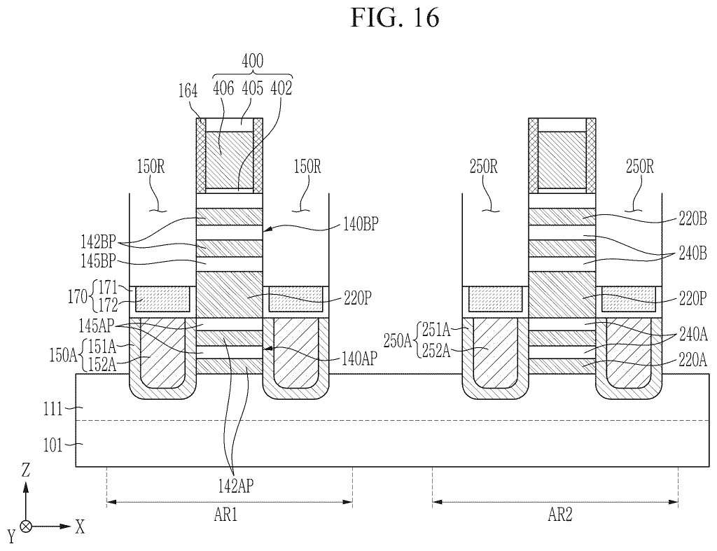

As shown in FIG. 16, the lower semiconductor pattern 150A and the barrier structure 170 may be formed within the first recess 150R in the first region AR1 of the substrate 101. In addition, the lower source/drain pattern 250A and the barrier structure 170 may be formed within the second recess 250R in the second region AR2 of the substrate 101.

The lower semiconductor pattern 150A may be the epitaxial pattern formed by the selective epitaxial growth process using the active pattern 111 and the plurality of first preliminary lower semiconductor layers 145AP as its seeds. In detail, the first sub-lower pattern 151A may be formed along the inner wall and lower surface of the first recess 150R, and the lower semiconductor pattern 150A may be formed by forming the second sub-lower pattern 152A on the first sub-lower pattern 151A. The lower semiconductor pattern 150A may be in contact with the active pattern 111 and the plurality of first preliminary lower semiconductor layers 145AP. The upper surface of the lower semiconductor pattern 150A may be disposed at substantially the same distance from an upper surface of the preliminary lower sheet structure 140AP and an upper surface of the substrate 101.

In some example embodiments, the lower semiconductor pattern 150A may have the first-type conductivity. The lower semiconductor pattern 150A may be doped with the first-type conductivity impurities. Here, the first-type conductivity may be the P-type conductivity, but example embodiments are not limited thereto. For example, the lower semiconductor pattern 150A may include boron (B), vanadium (V), indium (In), gallium (Ga), aluminum (Al), or the combination thereof. However, example embodiments are not limited thereto.

The lower source/drain pattern 250A may be the epitaxial pattern formed by the selective epitaxial growth process using the active pattern 111 and the plurality of lower channel patterns 240A as its seeds. In detail, the first lower source/drain layer 251A may be formed along the inner wall and lower surface of the second recess 250R, and the second lower source/drain layer 252A may be formed to fill the second recess 250R on top of the first lower source/drain layer 251A. The lower source/drain pattern 250A may be in contact with the active pattern 111 and the plurality of lower channel patterns 240A. An upper surface of the lower source/drain pattern 250A may be disposed at substantially the same distance from the upper surface of the lower semiconductor pattern 150A and the upper surface of the substrate 101.

In some example embodiments, the lower source/drain pattern 250A may include the same semiconductor material as the lower semiconductor pattern 150A. As an example, the lower source/drain pattern 250A and the lower semiconductor pattern 150A may include silicon (Si) or silicon germanium (SiGe), but example embodiments are not limited thereto.

In some example embodiments, the lower source/drain pattern 250A may have the first-type conductivity. The lower semiconductor pattern 150A may be doped with the first-type conductivity impurities. Here, the first-type conductivity may be the P-type conductivity, but example embodiments are not limited thereto. For example, the lower source/drain pattern 250A may include boron (B), vanadium (V), indium (In), gallium (Ga), aluminum (Al), or the combination thereof. However, example embodiments are not limited thereto.

The barrier structure 170 may be formed on the lower semiconductor pattern 150A and the lower source/drain pattern 250A. The barrier structure 170 may include the first liner 171 extending along a side surface of the preliminary intermediate insulating structure 220P and the upper surface of the lower semiconductor pattern 150A and the barrier pattern 172 disposed on the first liner 171. The first liner 171 may be disposed on the upper surface of the lower source/drain pattern 250A. The first liner 171 and the barrier pattern 172 may include the various insulating materials. The first liner 171 and the barrier pattern 172 may include different materials, but example embodiments are not limited thereto. For example, the first liner 171 may include silicon nitride, silicon oxynitride, or the combination thereof, and the barrier pattern 172 may include silicon oxide, silicon nitride, silicon oxynitride, or the combination thereof. However, example embodiments are not limited thereto.

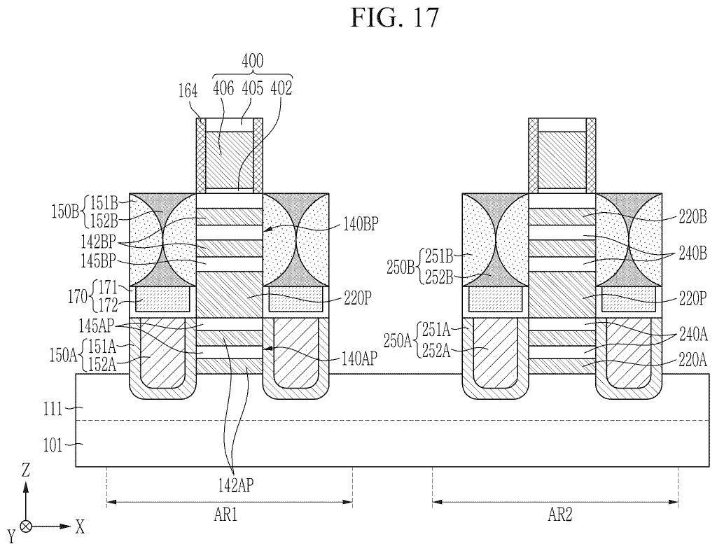

As shown in FIG. 17, the upper semiconductor pattern 150B may be formed on the barrier structure 170 in the first region AR1 of the substrate 101, and the upper source/drain pattern 250B may be formed on the barrier structure 170 in the second region AR2 of the substrate.

The upper semiconductor pattern 150B may be the epitaxial pattern formed by the selective epitaxial growth process using the plurality of first preliminary upper semiconductor layers 145BP as its seeds. In detail, the first sub-upper pattern 151B may be formed on a side surface of the plurality of first preliminary upper semiconductor layers 145BP, and the upper semiconductor pattern 150B may be formed by forming the second sub-upper pattern 152B on the first sub-upper pattern 151B. The upper surface of the upper semiconductor pattern 150B may be disposed at substantially the same distance from an upper surface of the preliminary upper sheet structure 140BP and the upper surface of the substrate 101.

In some example embodiments, the upper semiconductor pattern 150B may include the semiconductor material. The upper semiconductor pattern 150B may have the second-type conductivity. The upper semiconductor pattern 150B may be doped with the second-type conductivity impurities. Here, the second-type conductivity may be the N-type conductivity, but example embodiments are not limited thereto. For example, the upper semiconductor pattern 150B may include phosphorus (P), antimony (Sb), arsenic (As), or the combination thereof. However, example embodiments are not limited thereto.

The upper source/drain pattern 250B may be the epitaxial pattern formed by the selective epitaxial growth process using the plurality of upper channel patterns 240B as its seeds. In detail, the first upper source/drain layer 251B may be formed along the side surface of the plurality of upper channel patterns 240B, and the second upper source/drain layer 252B may be formed to fill the second recess 250R on top of the first upper source/drain layer 251B. The upper source/drain pattern 250B may be in contact with the plurality of upper channel patterns 240B. The upper surface of the lower source/drain pattern 250A may be disposed at substantially the same distance from the upper surface of the lower semiconductor pattern 150A and the upper surface of the substrate 101.

In some example embodiments, the upper source/drain pattern 250B may include the same semiconductor material as the upper semiconductor pattern 150B. As an example, the upper source/drain pattern 250B and the upper semiconductor pattern 150B may include silicon (Si) or silicon germanium (SiGe), but example embodiments are not limited thereto.

In some example embodiments, the upper source/drain pattern 250B may include the semiconductor material. The upper source/drain pattern 250B may have the second-type conductivity. The upper source/drain pattern 250B may be doped with the second-type conductivity impurities. Here, the second-type conductivity may be the N-type conductivity, but example embodiments are not limited thereto. For example, the upper source/drain pattern 250B may include phosphorus (P), antimony (Sb), arsenic (As), or the combination thereof. However, example embodiments are not limited thereto.

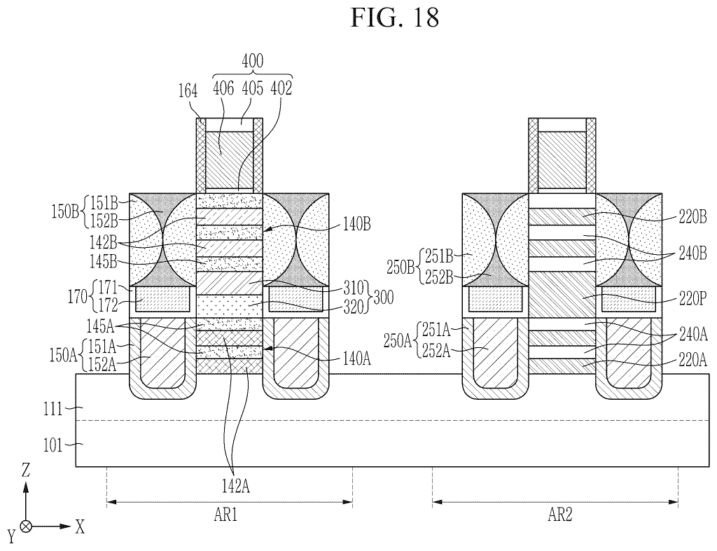

As shown in FIG. 18, in the first region AR1 of the substrate 101, the impurities in the lower semiconductor pattern 150A and the upper semiconductor pattern 150B may be diffused into their surroundings through the heat treatment process.

In detail, the lower sheet structure 140A may be formed by diffusing the impurities of the first-type conductivity, present in the lower semiconductor pattern 150A, into the preliminary lower sheet structure 140AP through the heat treatment process. For example, the impurities of the first-type conductivity may be diffused into the plurality of first preliminary lower semiconductor layers 145AP and the plurality of second preliminary lower semiconductor layers 142AP. Here, each of the impurities in the plurality of first preliminary lower semiconductor layers 145AP and the impurities in the plurality of second preliminary lower semiconductor layers 142AP may have a doping concentration less than or substantially equal to the doping concentration of the impurities in the lower semiconductor pattern 150A.

In addition, the first doped layer 320 may be formed by diffusing the impurities in the first-type conductivity, present in the lower semiconductor pattern 150A, into a portion of the preliminary intermediate insulating structure 220P through the heat treatment process. The first doped layer 320 may be formed as a portion of the preliminary intermediate insulating structure 220P. In addition, the impurities in the first doped layer 320 may have the doping concentration less than or substantially equal to the doping concentration of the impurities in the lower semiconductor pattern 150A.

In addition, the upper sheet structure 140B may be formed by diffusing the impurities in the second-type conductivity, present in the upper semiconductor pattern 150B, into the preliminary upper sheet structure 140BP through the heat treatment process. For example, the impurities in the second-type conductivity may be diffused into the plurality of first preliminary upper semiconductor layers 145BP and the plurality of second preliminary upper semiconductor layers 142BP. Here, each of the impurities in the plurality of first preliminary upper semiconductor layers 145BP and the impurities in the plurality of second preliminary upper semiconductor layers 142BP may have a doping concentration less than or substantially equal to the doping concentration of the impurities in the upper semiconductor pattern 150B.

In addition, the second doped layer 310 may be formed by diffusing the impurities in the second-type conductivity, present in the upper semiconductor pattern 150B, into a portion of the preliminary intermediate insulating structure 220P through the heat treatment process. The second doped layer 310 may be formed as a portion of the preliminary intermediate insulating structure 220P. Here, the impurities in the second doped layer 310 may have the doping concentration less than or substantially equal to the doping concentration of the impurities in the upper semiconductor pattern 150B.

In some example embodiments, PN junction interface 300_J may be formed by forming the first doped layer 320 and the second doped layer 310. In some example embodiments, the first doped layer 320 and the second doped layer 310 may form the PN junction interface 300_J (in FIG. 5). The PN junction interface 300_J (in FIG. 5) may be defined as the interface between the upper surface of the first doped layer 320 and the lower surface of the second doped layer 310. The upper surface of the first doped layer 320 may have the complementary shape to the lower surface of the second doped layer 310. The PN junction interface 300_J (in FIG. 5) may be flat on the cross section in the first-third direction (X-Z direction), but example embodiments are not limited thereto. As another example, as shown in the example embodiments as relating to FIG. 6, the PN junction interface 300_J (in FIG. 5) may be concave toward the upper surface of the lower sheet structure 140A. As still another example, as shown in the example embodiments relating to FIG. 7, the PN junction interface 300_J (in FIG. 5) may be convex toward the upper surface of the upper sheet structure 140B.

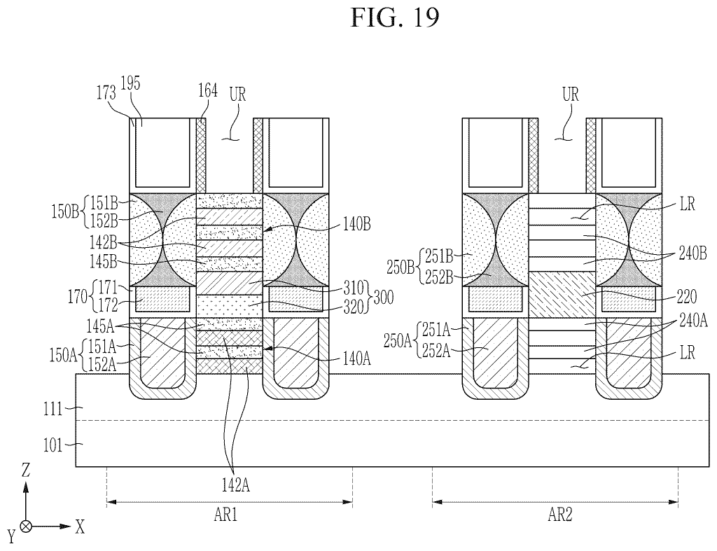

As shown in FIG. 19, the interlayer insulating layer 195 may first be formed on the upper source/drain pattern 250B and the upper semiconductor pattern 150B. Next, an upper gate trench UR may be formed by removing the sacrificial gate structure 400 from the first region AR1 and the second region AR2 of the substrate 101.

Next, the preliminary intermediate insulating structure 220P may be removed from the second region AR2 of the substrate 101, and the intermediate insulating structure 220 may then be formed in the removed region. The intermediate insulating structure 220 may include the various insulating materials. For example, the intermediate insulating structure 220 may include silicon oxide, silicon nitride, silicon oxynitride, or the combination thereof. However, example embodiments are not limited thereto. The intermediate insulating structure 220 may allow the plurality of lower channel patterns 240A and the plurality of upper channel patterns 240B to be spaced apart from each other.

Next, a lower gate trench LR may be formed between the plurality of channel patterns 240 by removing the upper sacrificial layer 220B and the lower sacrificial layer 220A. In some example embodiments, the lower gate trench LR is described as being formed after the intermediate insulating structure 220 is formed, but example embodiments are not limited thereto. As another example, the intermediate insulating structure 220 may be formed after forming the lower gate trench LR and forming the gate structures 260A, 260B, and 260M in the lower gate trench LR. In some example embodiments, processes of removing the sacrificial gate structure 400, the upper sacrificial layer 220B, and the lower sacrificial layer 220A may be simultaneously performed.

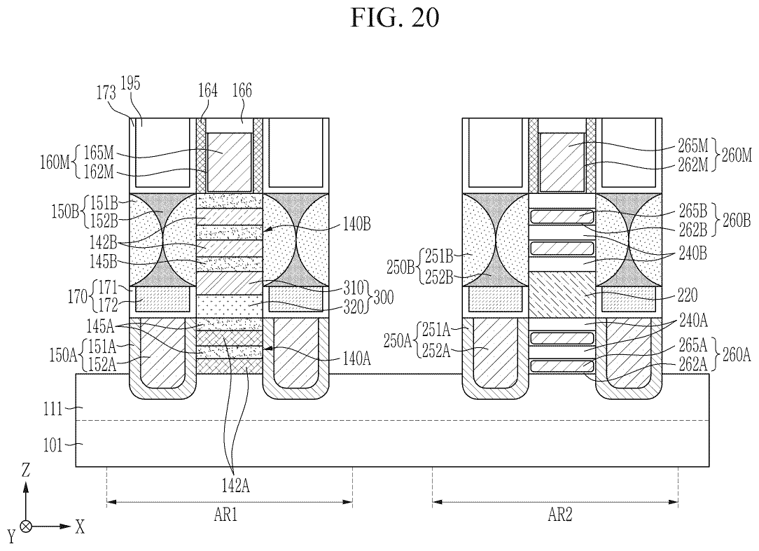

As shown in FIG. 20, the gate insulating films 262A and 262B may be formed in the lower gate trench LR, the dummy main gate insulating films 162M and 262M may be formed in the upper gate trench UR, the gate electrodes 265A and 265B and the dummy main gate electrodes 165M and 265M may then be formed, and the capping layer 166 may be formed on the dummy main gate electrodes 165M and 265M.

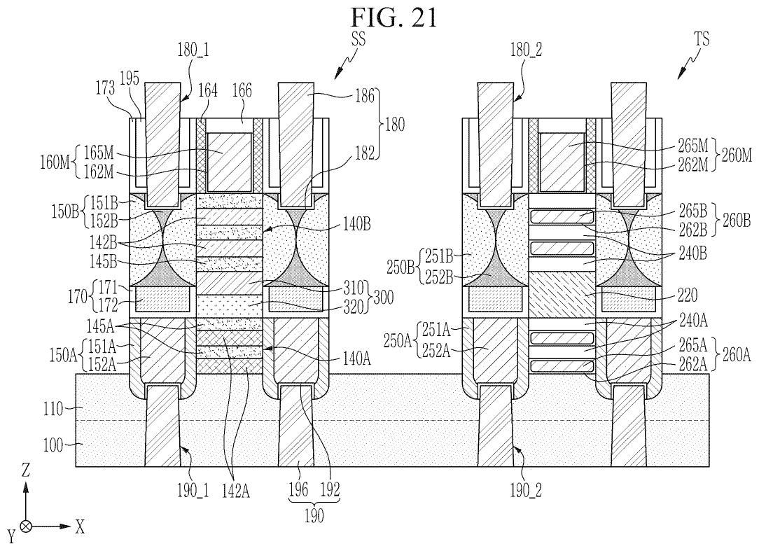

As shown in FIG. 21, the upper contact structure 180 may be formed by passing through the interlayer insulating layer 195, the base insulating layer 100 may be formed by removing the substrate 101 and the active pattern 111, and the lower contact structure 190 may then be formed by passing through the base insulating layer 100.

A contact hole may be first formed by passing through the interlayer insulating layer 195 to expose the upper source/drain pattern 250B and the upper semiconductor pattern 150B, and the upper contact structure 180 may then be formed to fill the contact hole. For example, the first upper contact structure 180_1 may be electrically connected to the upper semiconductor pattern 150B by passing through the interlayer insulating layer 195, and the second upper contact structure 180_2 may be electrically connected to the upper source/drain pattern 250B by passing through the interlayer insulating layer 195. The upper contact structure 180 may include the upper contact electrode 186 and the upper silicide film 182 disposed between the upper contact electrode 186 and the upper semiconductor pattern 150B.

Next, the substrate 101 and the active pattern 111 may be removed, and the base insulating layer 100 and the protruding pattern 110 may be formed in the removed space.

The base insulating layer 100 may be the insulation substrate. The base insulating layer 100 may include oxide, nitride, oxynitride, or the combination thereof. However, example embodiments are not limited thereto. For example, the base insulating layer 100 may include silicon oxide (SiO₂). The base insulating layer 100 is shown as the single film, which is only for the convenience of description, but example embodiments are not limited thereto. The base insulating layer 100 may be formed by removing the substrate 101 and filling the removed portion of the substrate 101 with the insulating material. The protruding pattern 110 may be formed by removing the active pattern 111 and filling the removed portion of the active pattern 111 with the insulating material.

Finally, the lower contact structure 190 may be formed by passing through the base insulating layer 100 and the protruding pattern 110.

The contact hole may be formed by passing through the base insulating layer 100 and the protruding pattern 110 to expose the lower source/drain pattern 250A and the lower semiconductor pattern 150A, and the lower contact structure 190 may then be formed to fill the contact hole. For example, the first lower contact structure 190-1 may be electrically connected to the lower semiconductor pattern 150A by passing through the base insulating layer 100 and the protruding pattern 110, and the second lower contact structure 190_2 may be electrically connected to the lower source/drain pattern 250A by passing through the base insulating layer 100 and the protruding pattern 110. The lower contact structure 190 may include the lower contact electrode 196 and the lower silicide film 192 disposed between the lower contact electrode 196 and the lower semiconductor pattern 150A.

Accordingly, the stacked structure SS and transistor structure TS of the semiconductor device may be formed according to some example embodiments.

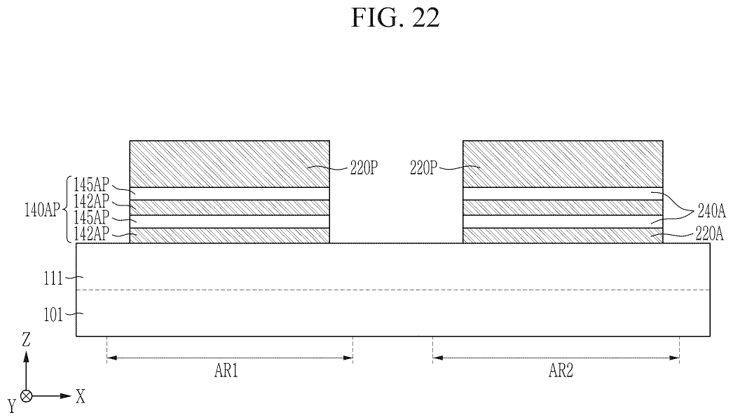

Hereinafter, a manufacturing method of a semiconductor device according to some example embodiments is described with reference to FIGS. 22 to 24.

FIGS. 22 to 24 are cross-sectional views showing intermediate stages of the method for manufacturing a semiconductor device according to some example embodiments.

As shown in FIG. 22, the preliminary lower sheet structure 140AP and the preliminary intermediate insulating structure 220P may be formed in the first region AR1 of the substrate 101. In addition, the lower sacrificial layer 220A, the plurality of lower channel patterns 240A, and the preliminary intermediate insulating structure 220P may be formed in the second region AR2 of the substrate 101.

In some example embodiments, the substrate 101 may include the first region AR1 and the second region AR2. The second region AR2 may be disposed in one side of the first region AR1 in the first direction (X direction), but example embodiments are not limited thereto. The first region AR1 may be a region where the stacked structure SS (in FIG. 2), as shown in the example embodiments relating to FIGS. 1 to 5, are formed. The second region AR2 may be a region where the transistor structure TS (in FIG. 2), as shown in the example embodiments relating to FIGS. 1 to 5, are formed.

A process of forming the preliminary lower sheet structure 140AP and the preliminary intermediate insulating structure 220P in the first region AR1 of the substrate 101 and a process of forming the lower sacrificial layer 220A, the plurality of lower channel patterns 240A, and the preliminary intermediate insulating structure 220P in the second region AR2 of the substrate 101 are substantially the same as those described in the embodiments shown in FIGS. 14 to 21, and the description thus omits their descriptions.

In some example embodiments, the preliminary intermediate insulating structure 220P may include the semiconductor material. As an example, the preliminary intermediate insulating structure 220P may include silicon germanium (SiGe). Here, the germanium (Ge) content (at %) in the preliminary intermediate insulating structure 220P may be different from the germanium (Ge) content (at %) in the plurality of second preliminary lower semiconductor layers 142AP, but example embodiments are not limited thereto.

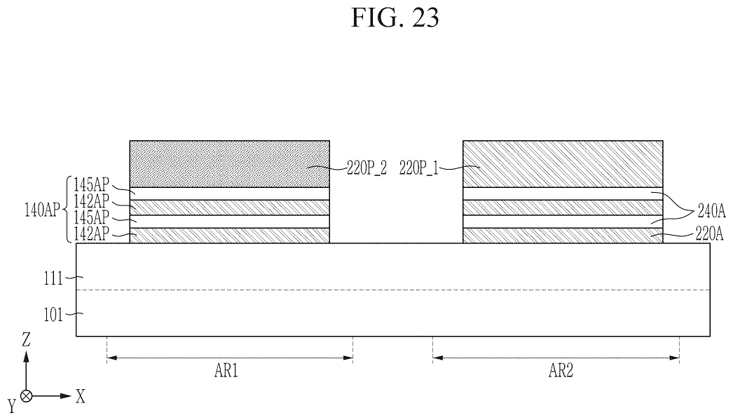

As shown in FIG. 23, in some example embodiments, the semiconductor material may be injected into a portion of the preliminary intermediate insulating structure 220P disposed in the first region AR1 of the substrate 101. A process of injecting the semiconductor material into a portion of the preliminary intermediate insulating structure 220P disposed in the first region AR1 of the substrate 101 may be performed using an ion implant process. For example, germanium (Ge) may be injected into a portion of the preliminary intermediate insulating structure 220P disposed in the first region AR1 of the substrate 101. Accordingly, a germanium (Ge) content (at %) in a first preliminary intermediate insulating structure 220P_2 disposed in the first region AR1 of the substrate 101 may be greater than a germanium (Ge) content (at %) in a second preliminary intermediate insulating structure 220P_1 disposed in the second region AR2 of the substrate 101.

In the subsequent process, the PN junction structure 300 may be formed through the process of injecting the impurities into the first preliminary intermediate insulating structure 220P. In some example embodiments, the process of injecting the impurities into the first preliminary intermediate insulating structure 220P may be separately performed, thereby easily forming the PN junction structure 300 having the germanium (Ge) content (at %) different from that in the second preliminary intermediate insulating structure 220P.

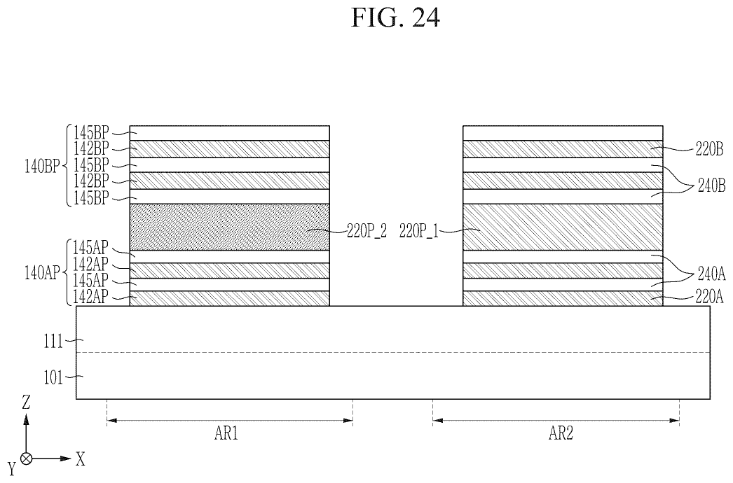

As shown in FIG. 24, the preliminary upper sheet structure 140BP may be formed on the first preliminary intermediate insulating structure 220P, and the upper sacrificial layer 220B and the plurality of upper channel patterns 240B may be formed on the second preliminary intermediate insulating structure 220P. Next, the same process as shown in the example embodiments relating to FIGS. 15 to 21 may be performed to thus form the semiconductor device according to some example embodiments.

Although example embodiments of the present disclosure have been described in detail hereinabove, the scope of the present disclosure is not limited thereto. That is, various modifications and alterations made by those skilled in the art that use a basic concept of the present disclosure as defined in the following claims also fall within the scope of the present disclosure.

What is claimed is:

1. A semiconductor device comprising:
a lower sheet structure including a plurality of first lower semiconductor layers and a plurality of second lower semiconductor layers alternately stacked;
an upper sheet structure including a plurality of first upper semiconductor layers and a plurality of second upper semiconductor layers alternately stacked on the lower sheet structure;
a lower semiconductor pattern on at least one side of the lower sheet structure;
an upper semiconductor pattern on at least one side of the upper sheet structure; and
a PN junction structure between the lower sheet structure and the upper sheet structure, the PN junction structure including a P-type and an N-type semiconductor material,
wherein the PN junction structure includes
a first doped layer having first-type conductivity on the lower sheet structure, and
a second doped layer having second-type conductivity on the first doped layer.

2. The semiconductor device of claim 1, wherein
the lower semiconductor pattern and the lower sheet structure have a same conductivity, and
the upper semiconductor pattern and the upper sheet structure have the same conductivity.

3. The semiconductor device of claim 2, wherein
the lower sheet structure has the first-type conductivity, and
the upper sheet structure has the second-type conductivity.

4. The semiconductor device of claim 3, wherein
first-type conductivity impurities in the first doped layer have a doping concentration less than or equal to a doping concentration of the first-type conductivity impurities in the lower semiconductor pattern.

5. The semiconductor device of claim 3, wherein
first-type conductivity impurities in the first doped layer have a doping concentration less than or equal to a doping concentration of the first-type conductivity impurities in the lower sheet structure.

6. The semiconductor device of claim 3, wherein
the plurality of first lower semiconductor layers and the plurality of second lower semiconductor layers each have the first-type conductivity, and
a doping concentration of first-type conductivity impurities in the plurality of first lower semiconductor layers is less than or equal to a doping concentration of the first-type conductivity impurities in the plurality of second lower semiconductor layers.

7. The semiconductor device of claim 1, wherein
first-type conductivity impurities in the first doped layer have a doping concentration of 10¹⁷ cm⁻³ to 10¹⁹ cm⁻³.

8. The semiconductor device of claim 1, wherein
the plurality of first lower semiconductor layers and the plurality of first upper semiconductor layers each include silicon, and
the plurality of second lower semiconductor layers and the plurality of second upper semiconductor layers each include silicon germanium.

9. The semiconductor device of claim 8, wherein
the PN junction structure includes silicon germanium, and
the PN junction structure has a germanium content (at %) different from a germanium content (at %) in the plurality of second upper semiconductor layers.

10. The semiconductor device of claim 1, wherein
at least a portion of the second doped layer overlaps the upper semiconductor pattern.

11. The semiconductor device of claim 1, wherein
an upper surface of the first doped layer is closer to an upper surface of the lower sheet structure than to a lower surface of the upper sheet structure.

12. The semiconductor device of claim 1, further comprising
a dummy main gate structure on the upper sheet structure,
wherein the dummy main gate structure covers a side surface of the upper sheet structure, a side surface of the lower sheet structure, and a side surface of the PN junction structure.

13. The semiconductor device of claim 1, further comprising
a barrier structure between the lower semiconductor pattern and the upper semiconductor pattern,
wherein at least a portion of the barrier structure overlaps the PN junction structure.

14. The semiconductor device of claim 13, wherein
a level of an upper surface of the first doped layer in a vertical direction is closer to a level of an upper surface of the barrier structure in the vertical direction than to a level of an upper surface of the lower sheet structure in the vertical direction,
the vertical direction being a direction perpendicular to the upper surface of the the lower sheet structure.

15. The semiconductor device of claim 13, wherein
a thickness of the PN junction structure is greater than a thickness of the barrier structure.

16. A semiconductor device comprising:
a lower sheet structure having first-type conductivity and including a plurality of first lower semiconductor layers and a plurality of second lower semiconductor layers alternately stacked;
an upper sheet structure having second-type conductivity and including a plurality of first upper semiconductor layers and a plurality of second upper semiconductor layers alternately stacked on the lower sheet structure;
a lower semiconductor pattern on at least one side of the lower sheet structure; and
a PN junction structure between the plurality of first lower semiconductor layers and the plurality of first upper semiconductor layers, the PN junction structure including a P-type and an N-type semiconductor material, and a same material as at least one of the plurality of second lower semiconductor layers and the plurality of second upper semiconductor layers,
wherein the PN junction structure includes
a first doped layer having the first-type conductivity on the lower sheet structure, and
a second doped layer having the second-type conductivity between the first doped layer and the upper sheet structure.

17. The semiconductor device of claim 16, wherein
first-type conductivity impurities in the first doped layer have a doping concentration less than or equal to a doping concentration of the first-type conductivity impurities in the lower sheet structure, and
a doping concentration of second-type conductivity impurities in the second doped layer is less than or equal to a doping concentration of the second-type conductivity impurities in the upper sheet structure.

18. The semiconductor device of claim 17, wherein
a doping concentration of the first-type conductivity impurities in the plurality of first lower semiconductor layers is less than or equal to a doping concentration of the first-type conductivity impurities in the plurality of second lower semiconductor layers, and
a doping concentration of the second-type conductivity impurities in the plurality of first upper semiconductor layers is less than or equal to a doping concentration of the second-type conductivity impurities in the plurality of second upper semiconductor layers.

19. The semiconductor device of claim 17, wherein
the doping concentration of the first-type conductivity impurities in the lower sheet structure is less than or equal to a doping concentration of the first-type conductivity impurities in the lower semiconductor pattern.

20. A semiconductor device comprising:
a base insulating layer;
a lower sheet structure including a plurality of first lower semiconductor layers and a plurality of second lower semiconductor layers alternately stacked on the base insulating layer;
an upper sheet structure including a plurality of first upper semiconductor layers and a plurality of second upper semiconductor layers alternately stacked on the lower sheet structure;
a lower semiconductor pattern having first-type conductivity on at least one side of the lower sheet structure;
an upper semiconductor pattern having second-type conductivity on at least one side of the upper sheet structure;
a barrier structure between the lower semiconductor pattern and the upper semiconductor pattern; and
a PN junction structure between the lower sheet structure and the upper sheet structure and overlapping the barrier structure, the PN junction structure including a P-type and an N-type semiconductor material,
wherein the PN junction structure includes
a first doped layer having the first-type conductivity on the lower sheet structure, and
a second doped layer having the second-type conductivity on the first doped layer, and
a doping concentration of first-type conductivity impurities in the first doped layer is less than or equal to a doping concentration of the first-type conductivity impurities in the lower semiconductor pattern.
